(19) United States
(12) Patent Application Publication
(10) Pub. No.: US 2026/0143252 A1
(43) Pub. Date: May 21, 2026

(54) PIXEL ARRAY OF IMAGE SENSOR AND IMAGE SENSOR INCLUDING THE SAME

(71) Applicant: SAMSUNG ELECTRONICS CO., LTD., Suwon-si (KR)

(72) Inventors: Sungyoon MIN, Suwon-si (KR); Jeongjin Cho, Suwon-si (KR)

(73) Assignee: SAMSUNG ELECTRONICS CO., LTD., Suwon-si (KR)

(21) Appl. No.: 19/320,096

(22) Filed: Sep. 5, 2025

(30) Foreign Application Priority Data
Nov. 15, 2024 (KR) 10-2024-0163402

(51) Int. Cl. H04N 25/59; H04N 25/77; H10F 39/00; H10F 39/18

(52) U.S. Cl. CPC H04N 25/59; H04N 25/77; H10F 39/182; H10F 39/8037; H10F 39/807

(57) ABSTRACT

A pixel array of an image sensor includes a plurality of first pixels and a plurality of second pixels spatially separated from the plurality of first pixels. Each of the plurality of first pixels includes a plurality of first photodiodes, a first floating diffusion region, a first reset transistor and at least one gain control transistor coupled in series between a pixel power supply voltage and the first floating diffusion region, and at least one gain control capacitor coupled with a ground voltage and coupled between the first reset transistor and the at least one gain control transistor. Each of the plurality of second pixels includes a plurality of second photodiodes, a second floating diffusion region, a second reset transistor coupled between a reset power supply voltage and the second floating diffusion region, and a lateral overflow integration capacitor coupled with a capacitor power supply voltage.

### CROSS-REFERENCE TO RELATED APPLICATIONS

This application claims benefit of priority under 35 U.S.C. § 119 to Korean Patent Application No. 10-2024-0163402, filed on Nov. 15, 2024, in the Korean Intellectual Property Office, the disclosure of which is incorporated by reference herein in its entirety.

### BACKGROUND

### 1. Field

The present disclosure relates generally to semiconductor integrated circuits, and more particularly, to pixel arrays of image sensors and image sensors including the pixel arrays.

### 2. Description of Related Art

An image sensor may refer to a device for capturing a two-dimensional and/or a three-dimensional image of an object. The image sensor may generate an image of an object using a photoelectric transducer that may respond to the intensity of light reflected from the object.

Recently, demand for image sensors with improved performance in various fields may be increasing. A complementary metal oxide semiconductor (CMOS) image sensor may refer to an image pickup device manufactured using a CMOS process. As compared to a charge-coupled device (CCD) image sensor, the CMOS image sensor may have advantages of relatively low manufacturing cost, relatively low power consumption, and/or relatively high integration.

However, an image obtained using a CMOS image sensor may be significantly affected by a signal-to-noise ratio (SNR) of the CMOS image sensor. For example, a signal-to-noise ratio dip (SNR dip) phenomenon, in which the signal-to-noise ratio may sharply decrease when synthesizing low-illuminance and/or high-illuminance images, may be a factor that may deteriorate the image quality. Thus, there exists a need for further improvements in image sensor technology, as the need for improved image quality may be constrained by signal-to-noise ratios of the image sensors. Improvements are presented herein. These improvements may also be applicable to other image capture technologies.

### SUMMARY

One or more example embodiments of the present disclosure provide a pixel array of an image sensor capable of having improved performance and reducing development difficulty and cost, when compared to related image sensors.

Further, one or more example embodiments of the present disclosure provide an image sensor including the pixel array.

According to an aspect of the present disclosure, a pixel array of an image sensor includes a plurality of first pixels and a plurality of second pixels spatially separated from the plurality of first pixels. Each first pixel of the plurality of first pixels includes a plurality of first photodiodes configured to generate first photocharges based on incident light, a first floating diffusion region configured to accumulate the first photocharges, the first floating diffusion region is shared by the plurality of first photodiodes, a first reset transistor and at least one gain control transistor coupled in series between a pixel power supply voltage and the first floating diffusion region, and at least one gain control capacitor coupled with a ground voltage and coupled between the first reset transistor and the at least one gain control transistor, the at least one gain control capacitor is configured to selectively accumulate the first photocharges. Each second pixel of the plurality of second pixels includes a plurality of second photodiodes configured to generate second photocharges based on the incident light, a second floating diffusion region configured to accumulate the second photocharges, the second floating diffusion region is shared by the plurality of second photodiodes, a second reset transistor coupled between a reset power supply voltage and the second floating diffusion region, and a lateral overflow integration capacitor coupled with a capacitor power supply voltage, the lateral overflow integration capacitor is configured to selectively accumulate the second photocharges.

According to an aspect of the present disclosure, an image sensor includes a pixel array, a row driver configured to drive the pixel array by units of rows, and a readout block configured to generate a plurality of output signals based on a plurality of pixel signals output from the pixel array. The pixel array including a plurality of first pixels and a plurality of second pixels. A first configuration of the plurality of first pixels is different from a second configuration of the plurality of second pixels. The plurality of first pixels are spatially separated from the plurality of second pixels. Each first pixel of the plurality of first pixels includes a plurality of first photodiodes configured to generate first photocharges based on incident light, a first floating diffusion region configured to accumulate the first photocharges, the first floating diffusion region is shared by the plurality of first photodiodes, a first reset transistor and at least one gain control transistor coupled in series between a pixel power supply voltage and the first floating diffusion region, and at least one gain control capacitor coupled to a ground voltage and coupled between the first reset transistor and the at least one gain control transistor, the at least one gain control capacitor is configured to selectively accumulate the first photocharges. Each second pixel of the plurality of second pixels includes a plurality of second photodiodes configured to generate second photocharges based on the incident light, a second floating diffusion region configured to accumulate the second photocharges, the second floating diffusion region is shared by the plurality of second photodiodes, a second reset transistor coupled between a reset power supply voltage and the second floating diffusion region, and a lateral overflow integration capacitor coupled to a capacitor power supply voltage, the lateral overflow integration capacitor is configured to selectively accumulate the second photocharges.

According to an aspect of the present disclosure, a pixel array of an image sensor includes a semiconductor substrate, a plurality of first pixels and a plurality of second pixels disposed in and on the semiconductor substrate, a first configuration of the plurality of first pixels is different from a second configuration of the plurality of second pixels, and a deep trench isolation pattern extending vertically in the semiconductor substrate, and at least partially surrounding each first pixel of the plurality of first pixels and each second pixel of the plurality of second pixels in a plan view, the plurality of first pixels and the plurality of second pixels are spatially separated by the deep trench isolation pattern. Each first pixel of the plurality of first pixels includes a plurality of first photodiodes configured to generate first photocharges based on incident light, a first floating diffusion region configured to accumulate the first photocharges, the first floating diffusion region is shared by the plurality of first photodiodes, a plurality of first transfer transistors coupled between the plurality of first photodiodes and the first floating diffusion region, respectively, a first reset transistor, a first gain control transistor and a second gain control transistor coupled in series between a pixel power supply voltage and the first floating diffusion region, a first gain control capacitor coupled between a first node and a ground voltage, the first node is between the first gain control transistor and the second gain control transistor, a second gain control capacitor coupled between a second node and the ground voltage, the second node is between the first reset transistor and the first gain control transistor, and a first driving transistor and a first selection transistor coupled in series between the pixel power supply voltage and a first output terminal, the first driving transistor having a first gate coupled with the first floating diffusion region, the first selection transistor having a second gate coupled with a first selection signal. Each second pixel of the plurality of second pixels includes a plurality of second photodiodes configured to generate second photocharges based on the incident light, a second floating diffusion region configured to accumulate the second photocharges, the second floating diffusion region is shared by the plurality of second photodiodes, a plurality of second transfer transistors coupled between the plurality of second photodiodes and the second floating diffusion region, respectively, a second reset transistor coupled between a reset power supply voltage and the second floating diffusion region, a lateral overflow integration capacitor coupled between a capacitor power supply voltage and the second floating diffusion region, the lateral overflow integration capacitor is configured to selectively accumulate the second photocharges, a discharge transistor coupled between the second reset transistor and the lateral overflow integration capacitor, and a second driving transistor and a second selection transistor coupled in series between the pixel power supply voltage and a second output terminal. The second driving transistor has a third gate coupled with the second floating diffusion region. The second selection transistor has a fourth gate with a second selection signal.

According to an aspect of the present disclosure, the pixel array and the image sensor may include the plurality of first pixels and the plurality of second pixels that commonly have the floating diffusion region shared configuration and have different configurations. For example, the plurality of first pixels may have the multi-gain control configuration, the plurality of second pixels may have the lateral overflow integration capacitor (LOFIC) configuration, and thus the pixels having the multi-gain control configuration and the pixels having the LOFIC configuration may be arranged together within one pixel array. Accordingly, both the prevention of the image quality deterioration caused by the SNR dip phenomenon and the high dynamic range may be achieved.

According to an aspect of the present disclosure, the pixel array and the image sensor may be implemented by changing only some pixels in the pixel array to have the LOFIC configuration. As compared to changing all pixels in a pixel array to additionally have the LOFIC configuration, the modification of the pixel layout may be unnecessary, the pixel configuration may be simplified, and thus the development difficulty and cost may be reduced. Further, the operating speed may be improved and the power consumption may be reduced during the operation of the image sensor, when compared to a related image sensor.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a plan view of a pixel array of an image sensor, according to example embodiments;

FIG. 2 is a plan view of an example of a pixel array of an image sensor of FIG. 1, according to example embodiments;

FIGS. 3A, 3B, and 3C are diagrams illustrating an example of a first pixel and a second pixel included in a pixel array of an image sensor of FIG. 2, according to example embodiments;

FIGS. 4A, 4B, 5A, 5B, and 5C are plan views of examples of a pixel array of an image sensor of FIG. 1, according to example embodiments;

FIG. 6 is a circuit diagram illustrating an example of a first pixel included in a pixel array of an image sensor, according to example embodiments;

FIG. 7 is a timing diagram illustrating an operation of a first pixel of FIG. 6, according to example embodiments;

FIG. 8 is a circuit diagram illustrating an example of first pixels included in a pixel array of an image sensor, according to example embodiments;

FIG. 9 is a circuit diagram illustrating an example of a first pixel included in a pixel array of an image sensor, according to example embodiments;

FIG. 10 is a timing diagram illustrating an operation of a first pixel of FIG. 9, according to example embodiments;

FIG. 11 is a circuit diagram illustrating an example of first pixels included in a pixel array of an image sensor, according to example embodiments;

FIG. 12 is a circuit diagram illustrating an example of a second pixel included in a pixel array of an image sensor, according to example embodiments;

FIG. 13 is a timing diagram illustrating an operation of a second pixel of FIG. 12, according to example embodiments;

FIG. 14 is a circuit diagram illustrating an example of a second pixel included in a pixel array of an image sensor, according to example embodiments, according to example embodiments;

FIG. 15 is a timing diagram illustrating an operation of a second pixel of FIG. 14, according to example embodiments;

FIG. 16 is a block diagram illustrating an image sensor, according to example embodiments, according to example embodiments;

FIGS. 17A and 17B are diagrams illustrating an operation of an image sensor, according to example embodiments, according to example embodiments;

FIG. 18 is a block diagram illustrating an image sensor, according to example embodiments, according to example embodiments;

FIG. 19 is a block diagram illustrating an electronic device, according to example embodiments, according to example embodiments; and

FIG. 20 is a block diagram illustrating an example of a camera module included in an electronic device of FIG. 19, according to example embodiments;

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “SiN”, “SiO”, and the like may refer to a material made of elements included in each of the terms and is not a chemical formula representing a stoichiometric relationship.

Hereinafter, various embodiments of the present disclosure are described with reference to the accompanying drawings.

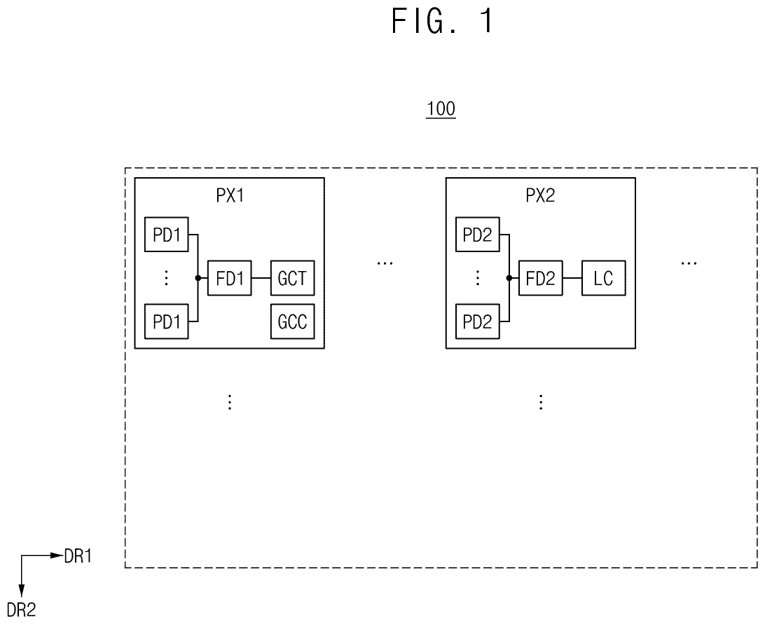

FIG. 1 is a plan view of a pixel array of an image sensor, according to example embodiments.

Referring to FIG. 1, a pixel array 100 of an image sensor may include a plurality of first pixels PX1 and a plurality of second pixels PX2. The plurality of first pixels PX1 and the plurality of second pixels PX2 may be pixels of different types, and may have different configurations.

The plurality of first pixels PX1 and the plurality of second pixels PX2 may be arranged along a first direction DR1 and a second direction DR2 crossing the first direction DR1. For example, the first direction DR1 may represent a row direction, and the second direction DR2 may represent a column direction.

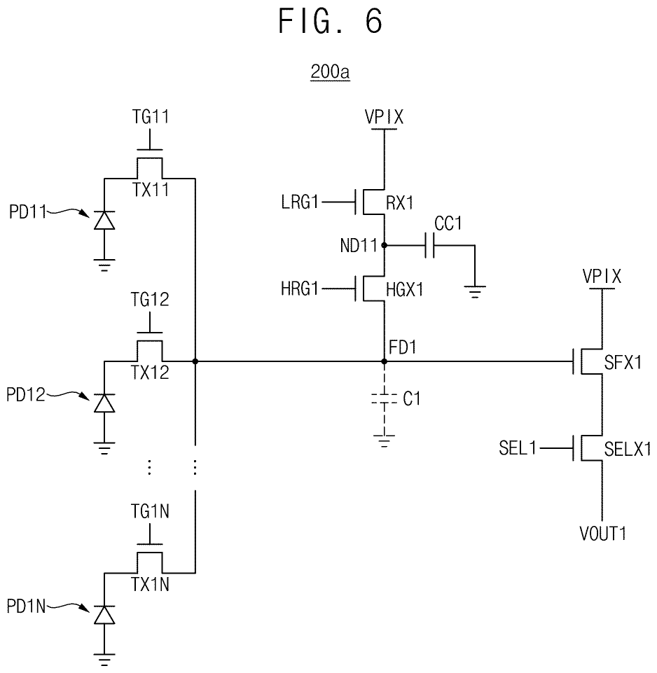

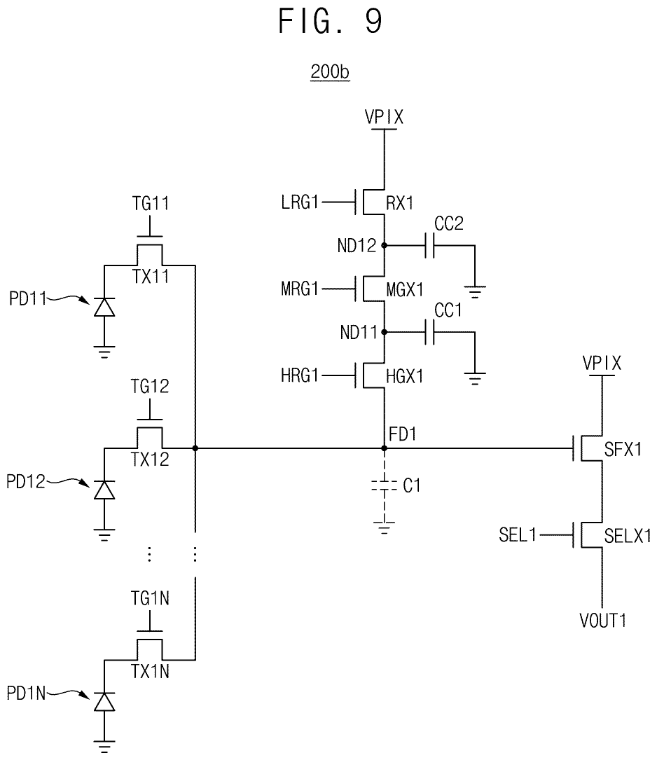

Each first pixel of the plurality of first pixels PX1 may include a plurality of first photodiodes PD1, a first floating diffusion region FD1, at least one gain control transistor GCT and at least one gain control capacitor GCC. As described with reference to FIGS. 6 and 9, each first pixel of the plurality of first pixels PX1 may further include a plurality of first transfer transistors, a first reset transistor, a first driving transistor, and a first selection transistor.

The plurality of first photodiodes PD1 may perform photoelectric conversion operations, and may generate first photocharges based on incident light. For example, the plurality of first photodiodes PD1 may convert the incident light into photocharges during an integration mode. If the image sensor including the pixel array 100 is a complementary metal oxide semiconductor (CMOS) image sensor, image information on an object to be captured may be obtained by collecting charge carriers (e.g., electron-hole pairs) in the plurality of first photodiodes PD1, which may be proportional to an intensity of the incident light, through an open shutter of the CMOS image sensor, during the integration mode.

The first floating diffusion region (or first floating diffusion node) FD1 may accumulate the first photocharges collected from the plurality of first photodiodes PD1 by the photoelectric conversion operations, and may be shared by the plurality of first photodiodes PD1. The image information may be generated based on the charge amount of the first photocharges transferred to the first floating diffusion region FD1.

As described above, a configuration in which a plurality of photodiodes share a single floating diffusion region may be referred to as a floating diffusion region shared configuration. Each first pixel of the plurality of first pixels PX1 may have the floating diffusion region shared configuration.

The at least one gain control transistor GCT may be connected to the first floating diffusion region FD1. The at least one gain control transistor GCT may be selectively turned on and/or off depending on illuminance (or illumination) of a driving environment of the image sensor including the pixel array 100. For example, when the illuminance of the driving environment is relatively low, the at least one gain control transistor GCT may be turned off. As another example, when the illuminance of the driving environment is relatively high, the at least one gain control transistor GCT may be turned on.

The at least one gain control capacitor GCC may be connected to the at least one gain control transistor GCT. The at least one gain control capacitor GCC may selectively accumulate the first photocharges depending on the on/off state of the at least one gain control transistor GCT. For example, when the at least one gain control transistor GCT is turned off, the at least one gain control capacitor GCC may be electrically disconnected from the first floating diffusion region FD1 so as not to accumulate the first photocharges, and each first pixel of the plurality of first pixels PX1 may accumulate the relatively small amount of photocharges. As another example, when the at least one gain control transistor GCT is turned on, the at least one gain control capacitor GCC may be electrically connected to the first floating diffusion region FD1 to accumulate the first photocharges, and each first pixel of the plurality of first pixels PX1 may accumulate the relatively large amount of photocharges. The amount of photocharges accumulated by each pixel may be associated with or related to a gain (or conversion gain) of each pixel. Therefore, a gain (or conversion gain) of each first pixel of the plurality of first pixels PX1 may be controlled and/or adjusted depending on the on/off state of the at least one gain control transistor GCT, thereby preventing the deterioration of image quality due to a signal-to-noise ratio dip (SNR dip) phenomenon.

As described above, a configuration in which a gain or conversion gain is changed using a gain control transistor and a gain control capacitor may be referred to as a multi-gain control configuration. Each first pixel of the plurality of first pixels PX1 may have the multi-gain control configuration.

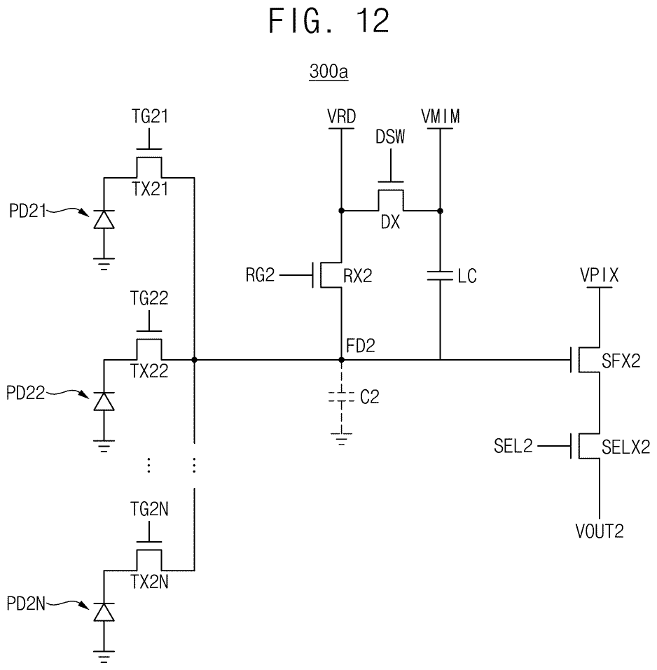

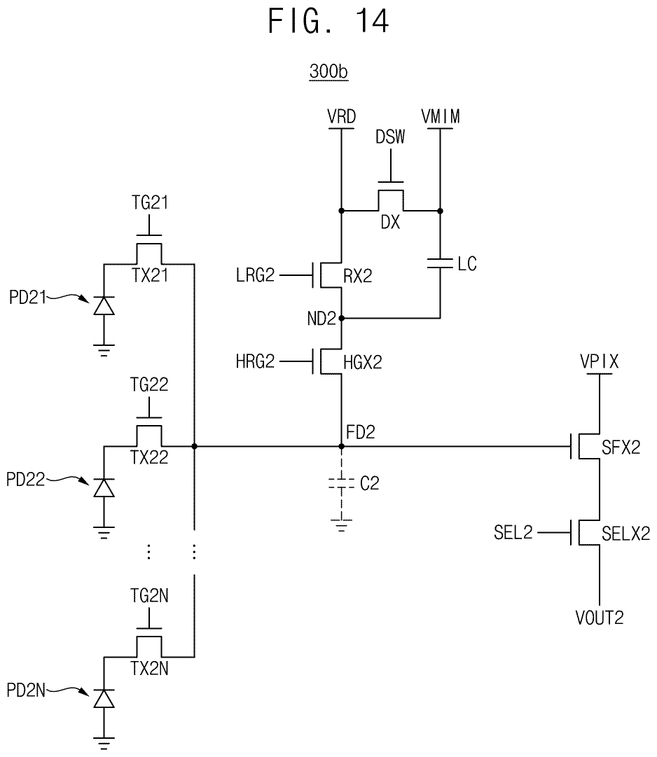

Each second pixel of the plurality of second pixels PX2 may include a plurality of second photodiodes PD2, a second floating diffusion region FD2 and a lateral overflow integration capacitor (LOFIC) LC. As described with reference to FIGS. 12 and 14, each second pixel of the plurality of second pixels PX2 may further include a plurality of second transfer transistors, a second reset transistor, a second driving transistor and a second selection transistor. The descriptions repeated with or overlapping with the plurality of first pixels PX1 may be omitted in the interest of brevity.

The plurality of second photodiodes PD2 may perform photoelectric conversion operations, and may generate second photocharges based on the incident light. The second floating diffusion region FD2 may accumulate the second photocharges collected from the plurality of second photodiodes PD2 by the photoelectric conversion operations, and may be shared by the plurality of second photodiodes PD2. Each second pixel of the plurality of second pixels PX2 may have the floating diffusion region shared configuration.

The lateral overflow integration capacitor LC may selectively accumulate the second photocharges. For example, from among the second photocharges collected from the plurality of second photodiodes PD2 by the photoelectric conversion operations, overflowed photocharges may be accumulated in the lateral overflow integration capacitor LC. As another example, when the illuminance of the driving environment is very high, the large amount of photocharges that may be overflowed from the plurality of second photodiodes PD2 may not be discarded and may be accumulated in the lateral overflow integration capacitor LC, thereby achieving a relatively high dynamic range, when compared to related image sensors.

As described above, a configuration including a lateral overflow integration capacitor may be referred to as a LOFIC configuration. Each second pixel of the plurality of second pixels PX2 may have the LOFIC configuration.

As described above, the plurality of first pixels PX1 may have both the floating diffusion region shared configuration and the multi-gain control configuration, and the plurality of second pixels PX2 may have both the floating diffusion region shared configuration and the LOFIC configuration. That is, the plurality of first pixels PX1 and the plurality of second pixels PX2 may be similar in that they have the floating diffusion region shared configuration, but may be different from each other in that they have the multi-gain control configuration and the LOFIC configuration, respectively.

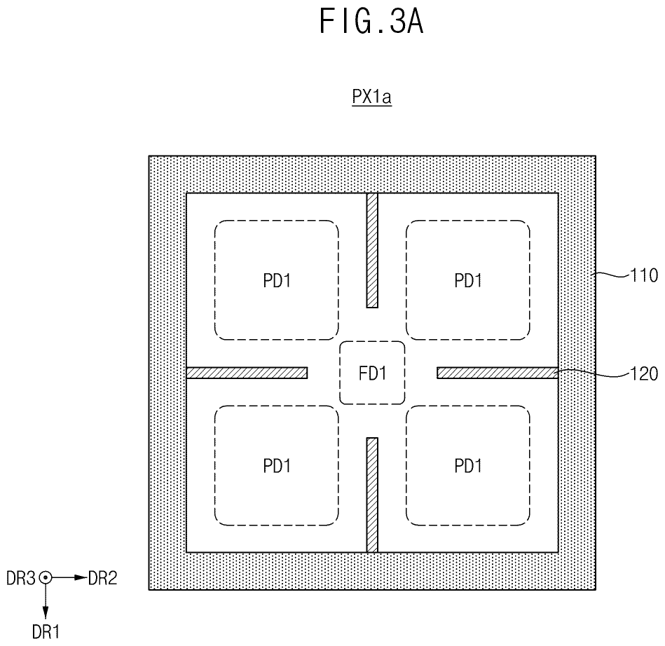

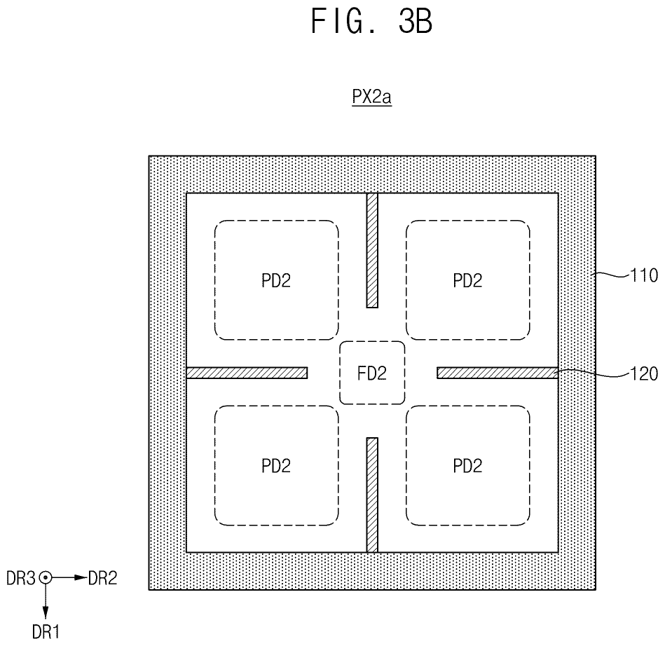

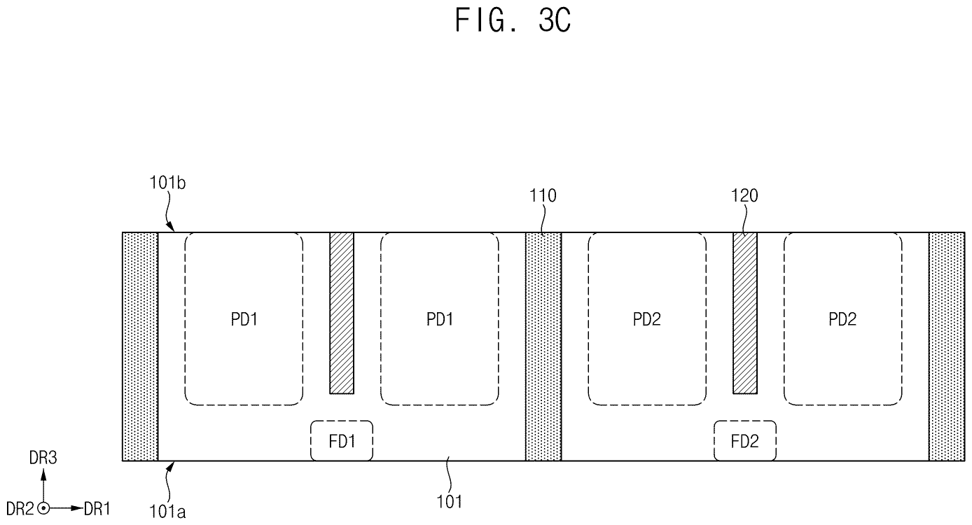

In some example embodiments, the plurality of first pixels PX1 and the plurality of second pixels PX2 may be spatially separated from each other. For example, as described with reference to FIGS. 3A, 3B, and 3C, the plurality of first pixels PX1 and the plurality of second pixels PX2 may be spatially separated by a deep trench isolation (DTI) structure.

In some example embodiments, the first number of the plurality of first pixels PX1 and the second number of the plurality of second pixels PX2 may be equal to each other. That is, a ratio of the first number and the second number may be about 1:1, and the second number may be about ½ of the total number of pixels including the pluralities of first and second pixels PX1 and PX2.

In some example embodiments, the second number of the plurality of second pixels PX2 may be smaller than the first number of the plurality of first pixels PX1. For example, the second number may be about ¼, ⅛, 1/16, or the like, of the total number of pixels including the pluralities of first and second pixels PX1 and PX2.

In some example embodiments, the image sensor including the pixel array 100 may operate in a full mode. In the full mode, one pixel signal may be generated from each photodiode, and a plurality of pixel signals may be output from one pixel. For example, the plurality of pixel signals may be generated and output by performing a plurality of sensing operations and/or a plurality of readout operations on the plurality of first photodiodes PD1 included in one first pixel PX1.

In some example embodiments, the image sensor including the pixel array 100 may operate in a binning mode. In the binning mode, signals generated from photodiodes included in one pixel may be summed to generate one pixel signal, and the one pixel signal may be output from one pixel. For example, the one pixel signal may be generated and output by performing one sensing operation and/or one readout operation on a plurality of first photodiodes PD1 included in one first pixel PX1. As another example, the operation of summing the signals generated from photodiodes included in one pixel in the binning mode may be implemented as a charge binning scheme in which photocharges collected in the photodiodes may be summed and read out and/or a digital binning scheme in which pixel signals output from photodiodes may be summed after digital conversion.

In some example embodiments, as described with reference to FIG. 6, each first pixel of the plurality of first pixels PX1 may include one gain control transistor and one gain control capacitor. In other example embodiments, as described with reference to FIG. 9, each first pixel of the plurality of first pixels PX1 may include two gain control transistors and two gain control capacitors. However, example embodiments are not limited thereto.

In some example embodiments, as described with reference to FIG. 12, each second pixel of the plurality of second pixels PX2 may have the lateral overflow integration capacitor LC that may be directly connected to the second floating diffusion region FD2. In some example embodiments, as described with reference to FIG. 14, each second pixel of the plurality of second pixels PX2 may have the lateral overflow integration capacitor LC that may be indirectly connected to the second floating diffusion region FD2. However, example embodiments are not limited thereto.

The pixel array 100 of the image sensor, according to example embodiments, may include the plurality of first pixels PX1 and the plurality of second pixels PX2 that commonly have the floating diffusion region shared configuration and have different configurations. For example, the plurality of first pixels PX1 may have the multi-gain control configuration, the plurality of second pixels PX2 may have the LOFIC configuration, and thus, the pixels PX1 having the multi-gain control configuration and the pixels PX2 having the LOFIC configuration may be arranged together within one pixel array 100. Accordingly, both the prevention of the image quality deterioration caused by the SNR dip phenomenon and the high dynamic range may be achieved.

In addition, the pixel array 100 of the image sensor, according to example embodiments, may be implemented by changing only some pixels in the pixel array 100 to have the LOFIC configuration. As compared to changing all pixels in a pixel array to additionally have the LOFIC configuration, the modification of the pixel layout may be unnecessary, the pixel configuration may be simplified, and thus the development difficulty and cost may be reduced. Further, the operating speed may be improved and the power consumption may be reduced during the operation of the image sensor.

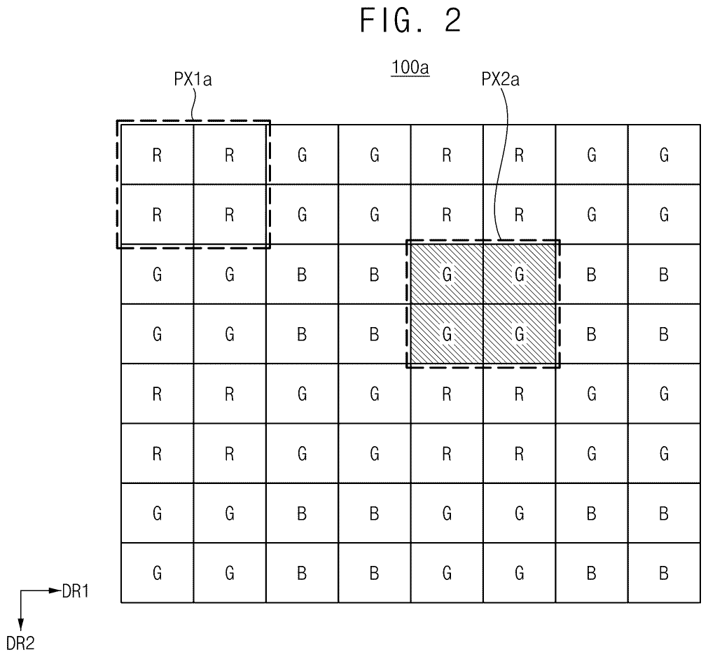

FIG. 2 is a plan view of an example of a pixel array of an image sensor of FIG. 1, according to example embodiments.

Referring to FIG. 2, an example where a pixel array 100a has RGGB color filter arrangement is illustrated, and an example where one pixel may include four photodiodes arranged in a 2×2 formation (e.g., where one floating diffusion region is shared by four (4) photodiodes) is illustrated. The 2×2 RGGB configuration may be referred to as the Tetra configuration.

In FIG. 2, one square may correspond to one color filter and one photodiode. In addition, the unhatched portions may represent first pixels having the multi-gain control configuration, and the hatched portions may represent second pixels having the LOFIC configuration.

For example, four (4) red R color filters in a 2×2 formation and four (4) photodiodes corresponding thereto may represent one first pixel PX1a, and four (4) green G color filters in a 2×2 formation and four (4) photodiodes corresponding thereto may represent one second pixel PX2a. Similarly, green G color filters in a 2×2 formation and photodiodes corresponding thereto may represent one first pixel, and blue B color filters in a 2×2 formation and photodiodes corresponding thereto may represent one first pixel.

That is, the pixel array 100a of FIG. 2 may include sixteen pixels, may include four (4) red R pixels, eight (8) green G pixels and four (4) blue B pixels, and may include fifteen first pixels and one second pixel. FIG. 2 illustrates an example where the number of the second pixels is smaller than the number of the first pixels. However, the number of pixels included in the pixel array 100a is not limited thereto, and the arrangement illustrated in FIG. 2 may be repeatedly disposed in the first direction DR1 and the second direction DR2. The positions of the second pixels and the color filters corresponding thereto may be variously determined, according to example embodiments.

FIGS. 3A, 3B, and 3C are diagrams illustrating an example of a first pixel and a second pixel included in a pixel array of an image sensor of FIG. 2, according to example embodiments. FIG. 3A is a plan view of the first pixel PX1a in FIG. 2, FIG. 3B is a plan view of the second pixel PX2a in FIG. 2, and FIG. 3C is a cross-sectional view of a vertical structure of the first pixel PX1a and a vertical structure of the second pixel PX2a.

Referring to FIGS. 3A, 3B, and 3C, the first pixel PX1a and the second pixel PX2a may be disposed in and on a semiconductor substrate 101. That is, the first pixel PX1a and the second pixel PX2a may be formed using the semiconductor substrate 101.

In FIGS. 3A, 3B, and 3C, two directions that are each parallel or substantially parallel to a first surface (e.g., a front surface or a top surface) 101a and a second surface (e.g., a back surface or a bottom surface) 101b of the semiconductor substrate 101 and crossing each other may be referred to as the first direction DR1 and the second direction DR2. In addition, a direction vertical or substantially vertical to the first surface 101a and the second surface 101b of the semiconductor substrate 101 is referred to as a third direction DR3 (e.g., a vertical direction). For example, the first and second directions DR1 and DR2 may be perpendicular or substantially perpendicular to each other. In addition, the third direction DR3 may be perpendicular or substantially perpendicular to both the first and second directions DR1 and DR2. Further, a direction indicated by an arrow in the figures and a reverse direction thereof are considered as the same direction. The first, second, and third directions DR1, DR2, and DR3 may be oriented in a same manner in the subsequent figures.

The semiconductor substrate 101 may have the first surface 101a and the second surface 101b that may be opposite to each other. For example, the semiconductor substrate 101 may be a substrate where an epitaxial layer having a first conductivity type (e.g., p-type) may be formed on a bulk silicon substrate having the first conductivity type, and may be a substrate where the bulk silicon substrate is removed in a manufacturing process of the image sensor, so that only the epitaxial layer may remain. Alternatively, the semiconductor substrate 101 may be a bulk semiconductor substrate including a well having the first conductivity type.

The first pixel PX1a may include first photodiodes PD1 and a first floating diffusion region FD1 that may be formed in the semiconductor substrate 101. The second pixel PX2a may include second photodiodes PD2 and a second floating diffusion region FD2 that may be formed in the semiconductor substrate 101.

In the first and second photodiodes PD1 and PD2, photocharges (e.g., electron-hole pairs) may be generated in proportion to the intensity of incident light, and the first and second photodiodes PD1 and PD2 may collect the photocharges. For example, the first and second photodiodes PD1 and PD2 may be and/or may include impurity regions doped with impurities of a second conductivity type (e.g., n-type) opposite to the first conductivity type of the semiconductor substrate 101. For example, the semiconductor substrate 101 and the first and second photodiodes PD1 and PD2 may be implemented by photodiodes. As another example, one photodiode may be formed by the junction of the semiconductor substrate 101 having the first conductive type and one photodiode having the second conductive type. However, example embodiments are not limited thereto, and each photodiode of the first and second photodiodes PD1 and PD2 may include a photodiode, a photo transistor, a photo gate, a pinned photodiode (PPD), and/or a combination thereof.

The first and second floating diffusion regions FD1 and FD2 may be respectively disposed at the center of the first and second pixels PX1a and PX2a to be shared by the first and second photodiodes PD1 and PD2, and may accumulate photocharges collected in the first and second photodiodes PD1 and PD2 by the photoelectric conversion operation. Similar to the first and second photodiodes PD1 and PD2, the first and second floating diffusion regions FD1 and FD2 may be or include impurity regions doped with impurities of the second conductivity type.

The pixel array 100a may further include a deep trench isolation pattern 110 and a shallow trench isolation pattern 120 that may be disposed and formed in the semiconductor substrate 101.

The deep trench isolation pattern 110 may extend in the third direction DR3 in the semiconductor substrate 101. For example, the deep trench isolation pattern 110 may extend in the third direction DR3 from the first surface 101a to the second surface 101b of the semiconductor substrate 101. As another example, a first surface of the deep trench isolation pattern 110 may be substantially coplanar with the first surface 101a of the semiconductor substrate 101, and a second surface of the deep trench isolation pattern 110 may be substantially coplanar with the second surface 101b of the semiconductor substrate 101.

The deep trench isolation pattern 110 may surround the first pixel PX1a and the second pixel PX2a in a plan view (or on a plane), and may have a mesh structure in a plan view. A pixel area in which each pixel is disposed may be defined by the deep trench isolation pattern 110, and the first pixel PX1a and the second pixel PX2a may be spatially separated and/or isolated from each other by the deep trench isolation pattern 110.

The shallow trench isolation pattern 120 may extend in the third direction DR3 in the semiconductor substrate 101. For example, the shallow trench isolation pattern 120 may extend in the third direction DR3 from the second surface 101b of the semiconductor substrate 101. A sub-pixel area in which each photodiode is disposed within each pixel area may be defined by the shallow trench isolation pattern 120.

A depth of the shallow trench isolation pattern 120 (e.g., a length of the shallow trench isolation pattern 120 in the third direction DR3) may be smaller than a depth of the deep trench isolation pattern 110 (e.g., a length of the deep trench isolation pattern 110 in the third direction DR3). For example, a first surface of the shallow trench isolation pattern 120 may not be coplanar with the first surface 101a of the semiconductor substrate 101, and a second surface of the shallow trench isolation pattern 120 may be substantially coplanar with the second surface 101b of the semiconductor substrate 101. In some example embodiments, a thickness of the shallow trench isolation pattern 120 (e.g., a length of the shallow trench isolation pattern 120 in the first direction DR1 or the second direction DR2) and a thickness of the deep trench isolation pattern 110 (e.g., a length of the deep trench isolation pattern 110 in the first direction DR1 or the second direction DR2) may be substantially similar and/or the same as or different from each other.

The deep trench isolation pattern 110 may prevent incident light on one pixel (e.g., the first pixel PX1a) and photocharges generated from the one pixel by the incident light from being transferred to another adjacent pixel (e.g., the second pixel PX2a). That is, the deep trench isolation pattern 110 may prevent a crosstalk phenomenon between adjacent pixels. The shallow trench isolation pattern 120 may prevent a crosstalk phenomenon between photodiodes included in one pixel (e.g., between the first photodiodes PD1 included in the first pixel PX1a).

In some example embodiments, the deep trench isolation pattern 110 may be formed by extending from the second surface 101b of the semiconductor substrate 101, and may be referred to as a back deep trench isolation (BDTI) structure. In other example embodiments, the deep trench isolation pattern 110 may be formed by extending from the first surface 101a of the semiconductor substrate 101, and it may be referred to as a front deep trench isolation (FDTI) structure. In some example embodiments, the shallow trench isolation pattern 120 may be formed by extending from the second surface 101b of the semiconductor substrate 101.

In some example embodiments, the deep trench isolation pattern 110 and the shallow trench isolation pattern 120 may be formed of an insulating material having a refractive index lower than that of the semiconductor substrate 101, and may include one or more insulating films. For example, the deep trench isolation pattern 110 and the shallow trench isolation pattern 120 may be formed of a silicon oxide (SiO) film, a silicon nitride (SiN) film, an undoped polysilicon film, air, and/or a combination thereof. For example, the deep trench isolation pattern 110 and the shallow trench isolation pattern 120 may include at least one of a liner insulating pattern, a semiconductor pattern, or a capping insulating pattern.

In some example embodiments, gate electrodes and wirings may be disposed and formed on the first surface 101a of the semiconductor substrate 101, and a light-shielding pattern, a color filter, a micro lens, or the like may be disposed and formed on the second surface 101b of the semiconductor substrate 101. For example, the light may be incident through the second surface 101b. That is, the image sensor including the pixel array 100a may be a backside illuminated image sensor (BIS) that may operate in response to incident light passing through the back surface of the semiconductor substrate 101.

In the BIS, since the gate electrodes and wirings connected to the gate electrodes may not be disposed between the micro lens and the photodiode, diffused reflection and/or scattering due to the gate electrodes and wirings may not occur, and a distance from the micro lens to the photodiode may be shorter. Accordingly, light guiding efficiency and light sensitivity may be improved in the backside illuminated image sensor. In addition, the wirings may not be limited to their positions, and may overlap with the photodiode.

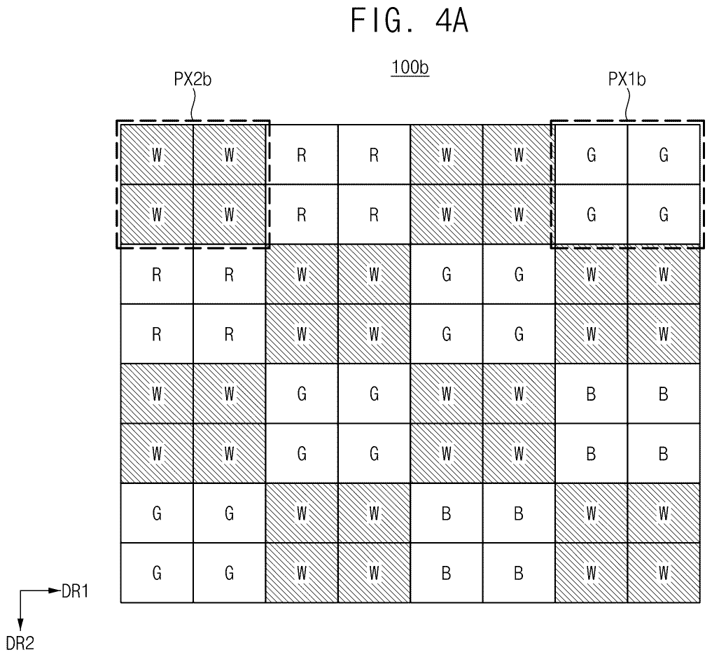

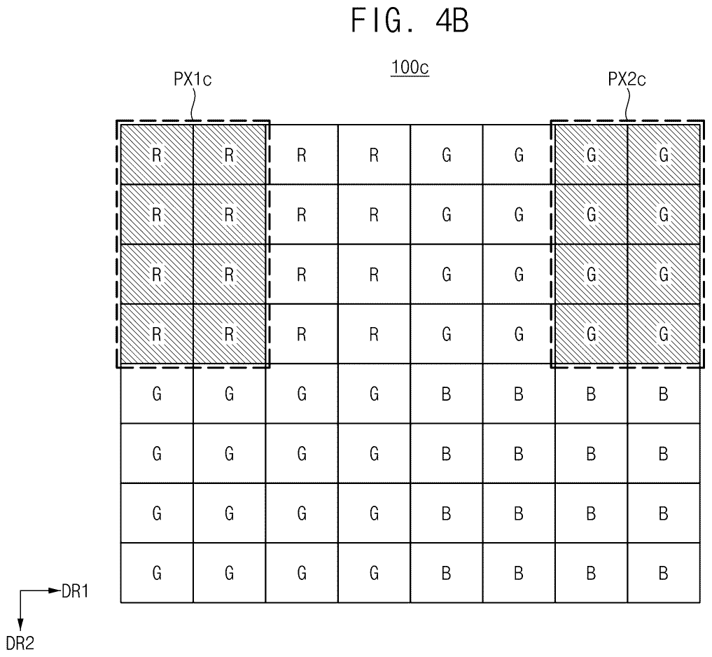

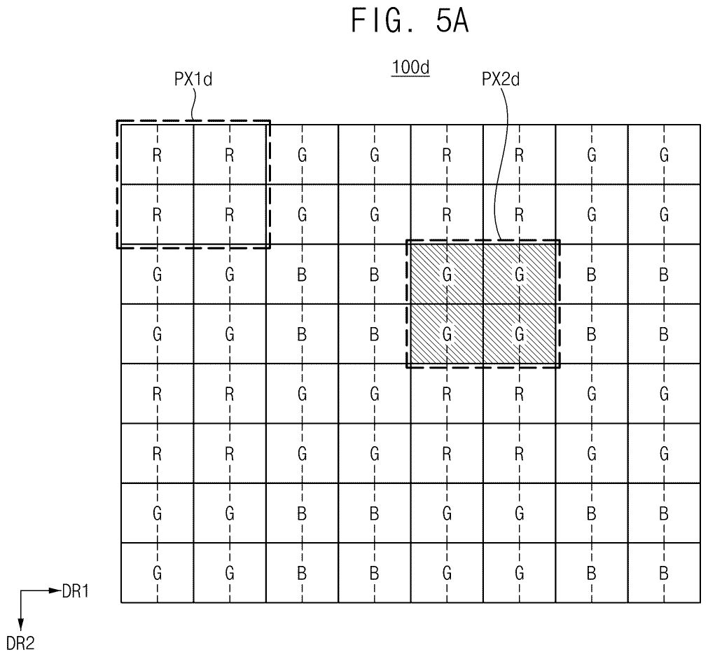

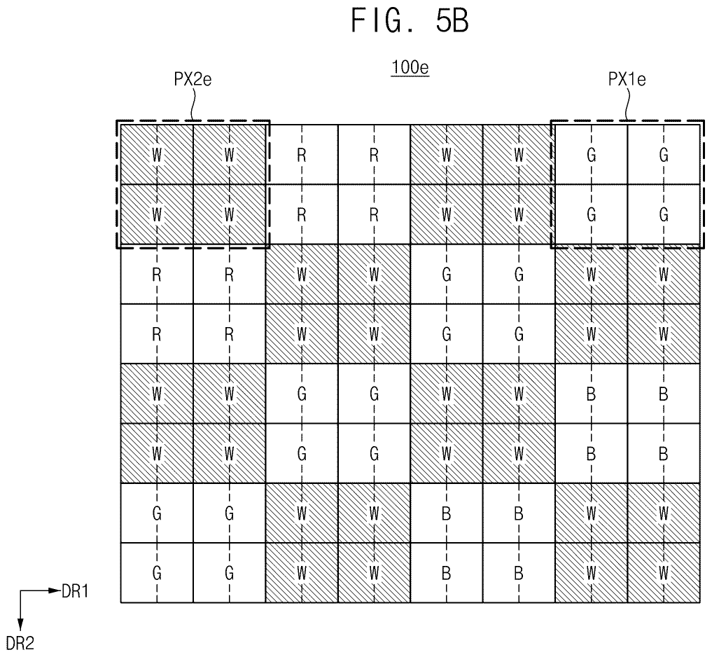

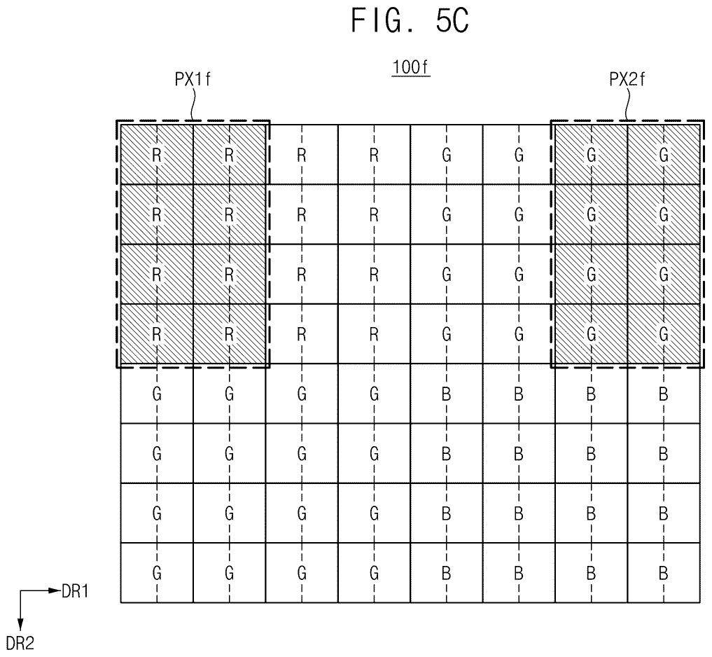

FIGS. 4A, 4B, 5A, 5B, and 5C are plan views of examples of a pixel array of an image sensor of FIG. 1, according to example embodiments. The descriptions repeated with or overlapping with descriptions of FIG. 2 may be omitted in the interest of brevity.

Referring to FIG. 4A, an example where a pixel array 100b has RGBW color filter arrangement is illustrated, and an example where one pixel may include four (4) photodiodes arranged in a 2×2 formation is illustrated.

For example, four (4) green G color filters in a 2×2 formation and four (4) photodiodes corresponding thereto may represent one first pixel PX1b, and four (4) white W color filters in a 2×2 formation and four (4) photodiodes corresponding thereto may represent one second pixel PX2b. Similarly, red R color filters in a 2×2 formation and photodiodes corresponding thereto may represent one first pixel, and blue B color filters in a 2×2 formation and photodiodes corresponding thereto may represent one first pixel.

That is, the pixel array 100b of FIG. 4A may include sixteen pixels, may include eight (8) white W pixels, two (2) red R pixels, four (4) green G pixels, and two (2) blue B pixels, and may include eight (8) first pixels and eight (8) second pixels. FIG. 4A illustrates an example where the number of second pixels and the number of first pixels are equal to each other.

Referring to FIG. 4B, an example where a pixel array 100c has RGGB color filter arrangement is illustrated, and an example where one pixel may include eight photodiodes arranged in a 2×4 formation is illustrated. The 4×4 RGGB configuration may be referred to as the Tetra2 configuration.

For example, eight (8) red R color filters in a 2×4 formation and eight (8) photodiodes corresponding thereto may represent one first pixel PX1c, and eight (8) green G color filters in a 2×4 formation and eight (8) photodiodes corresponding thereto may represent one second pixel PX2c. Similarly, green G color filters in a 2×4 formation and photodiodes corresponding thereto may represent one first pixel, and blue B color filters in a 2×4 formation and photodiodes corresponding thereto may represent one first pixel.

That is, the pixel array 100c of FIG. 4B may include eight (8) pixels, may include two (2) red R pixels, four (4) green G pixels and two (2) blue B pixels, and may include seven (7) first pixels and one (1) second pixel. FIG. 4B illustrates an example where the number of second pixels is smaller than the number of first pixels. In some example embodiments, the arrangement illustrated in FIG. 4B may be repeatedly disposed in the first direction DR1 and the second direction DR2, and the second pixels may not be disposed in some areas.

Referring to FIG. 5A, an example where a pixel array 100d has RGGB color filter arrangement is illustrated, and an example where one pixel may include eight (8) photodiodes arranged in a 2×4 formation is illustrated.

In FIG. 5A, a single square illustrated by a solid line may correspond to a single color filter, and a dotted line crossing a single square may correspond to two (2) photodiodes. That is, the pixel array 100d may have two (2) photodiode (2PD) configuration in which two (2) photodiodes for auto-focusing are included in one sub-pixel area.

A color filter arrangement of the pixel array 100d and configurations of a first pixel PX1d and a second pixel PX2d included in the pixel array 100d may be substantially similar and/or the same as the color filter arrangement of the pixel array 100a of FIG. 2 and the configurations of the first pixel PX1a and the second pixel PX2a of FIG. 2, respectively, except that the pixel array 100d has the 2PD configuration. The pixel array 100a of FIG. 2 may have one photodiode (1PD) configuration in which one photodiode is included in one sub-pixel area.

Referring to FIG. 5B, an example where a pixel array 100e has RGBW color filter arrangement is illustrated, and an example where one pixel may include eight (8) photodiodes arranged in a 2×4 formation is illustrated. A color filter arrangement of the pixel array 100e and configurations of a first pixel PX1e and a second pixel PX2e included in the pixel array 100e may be substantially similar and/or the same as the color filter arrangement of the pixel array 100b of FIG. 4A and the configurations of the first pixel PX1b and the second pixel PX2b in FIG. 4A, respectively, except that the pixel array 100e has the 2PD configuration.

Referring to FIG. 5C, an example where a pixel array 100f has RGGB color filter arrangement is illustrated, and an example where one pixel may include sixteen photodiodes arranged in a 4×4 formation is illustrated. A color filter arrangement of the pixel array 100f and configurations of a first pixel PX1f and a second pixel PX2f included in the pixel array 100f may be substantially similar and/or the same as the color filter arrangement of the pixel array 100c of FIG. 4B and the configurations of the first pixel PX1c and the second pixel PX2c in FIG. 4B, respectively, except that the pixel array 100f has the 2PD configuration.

Although example embodiments are described based on a specific color filter arrangement (e.g., RGGB or RGBW), a specific number of first and second pixels and a specific number of photodiodes (e.g., 1PD or 2PD), example embodiments are not limited thereto, and the color filter arrangement, the number of pixels and the number of photodiodes sharing the floating diffusion region may be variously determined, according to example embodiments. For example, the color filter arrangement may be implemented in various manners, such as RGB-IR, RYYB, CMY, CMYG, RWB, or the like. As another example, the pixel configuration may be implemented in various manners, such as 4PD, Q-cell, or the like.

FIG. 6 is a circuit diagram illustrating an example of a first pixel included in a pixel array of an image sensor, according to example embodiments.

Referring to FIG. 6, a first pixel 200a may include a plurality of first photodiodes (e.g., a first photodiode PD11, a second photodiode PD12, to a N-th photodiode PD1N, where N is a positive integer greater than one (1)), a plurality of first transfer transistors (e.g., a first transfer transistor TX11, a second transfer transistor TX12, to an N-th transfer transistor TX1N), a first floating diffusion region FD1, a first reset transistor RX1, a first gain control transistor HGX1, a first gain control capacitor CC1, a first driving transistor SFX1, and a first selection transistor SELX1.

The plurality of first photodiodes PD11 to PD1N and the first floating diffusion region FD1 may be substantially similar and/or the same as the plurality of first photodiodes PD1 and the first floating diffusion region FD1 in FIG. 1, respectively. The first gain control transistor HGX1 and the first gain control capacitor CC1 may be included in the at least one gain control transistor GCT and the at least one gain control capacitor GCC in FIG. 1, respectively.

The plurality of first transfer transistors TX11 to TX1N may be connected between the plurality of first photodiodes PD11 to PD1N and the first floating diffusion region FD1, respectively. Each transfer transistor of the plurality of first transfer transistors TX11 to TX1N may include a gate electrode receiving a respective one of a plurality of first transfer signals (e.g., a first transfer signal TG11, a second transfer signal TG12, to an N-th transfer signal TG1N).

The first reset transistor RX1 and the first gain control transistor HGX1 may be connected in series between a pixel power supply voltage VPIX and the first floating diffusion region FD1. The first reset transistor RX1 may include a gate electrode receiving a first reset signal LRG1, and the first gain control transistor HGX1 may include a gate electrode receiving a first high gain control signal HRG1.

The first gain control capacitor CC1 may be connected between a node ND11, which may be between the first reset transistor RX1 and the first gain control transistor HGX1, and a ground voltage.

The first driving transistor SFX1 and the first selection transistor SELX1 may be connected in series between the pixel power supply voltage VPIX and a first output terminal providing a first output voltage VOUT1. The first driving transistor SFX1 may include a gate electrode connected to the first floating diffusion region FD1, and the first selection transistor SELX1 may include a gate electrode receiving a first selection signal SEL1.

The first photocharges generated from the plurality of first photodiodes PD11 to PD1N may be transferred to the first floating diffusion region FD1 through the plurality of first transfer transistors TX11 to TX1N. The first floating diffusion region FD1, the first gain control capacitor CC1, or the like, may be initialized by the first reset transistor RX1. A gain (or conversion gain) of the first pixel 200a may be controlled or adjusted by the first gain control transistor HGX1 and the first gain control capacitor CC1. The first driving transistor SFX1 may operate as a source follower buffer amplifier to amplify a signal corresponding to the first photocharges accumulated in the first floating diffusion region FD1. The first pixel 200a may be selected based on the first selection transistor SELX1, and amplified signal (e.g., the first output voltage VOUT1) may be output or provided to a column line.

In some example embodiments, the gain (or conversion gain) of the first pixel 200a may be adjusted using the first gain control transistor HGX1 by changing a capacitance of the first floating diffusion region FD1 based on the first high gain control signal HRG1. For example, when the capacitance of the first floating diffusion region FD1 increases, the gain (or conversion gain) of the first pixel 200a may decrease.

For example, in a low-illuminance environment where the illuminance of the driving environment is lower than a reference illuminance, the first reset transistor RX1 and the first gain control transistor HGX1 may be turned off. In this example, the capacitance of the first floating diffusion region FD1 may correspond to C1.

As another example, in a high-illuminance environment where the illuminance of the driving environment is higher than or equal to the reference illuminance, the first reset transistor RX1 may be turned off, and the first gain control transistor HGX1 may be turned on. In this example, as compared to the low-illuminance environment, the capacitance of the first floating diffusion region FD1 may increase by a capacitance of the first gain control capacitor CC1 (e.g., the capacitance of the first floating diffusion region FD1 may correspond to C1+CC1), and thus a relatively large amount of photocharges may be accumulated.

As a result, a double conversion gain (DCG) may be implemented by selectively switching the first gain control transistor HGX1. As such, an example where one of two gains is selected using one gain control transistor may be referred to as a double gain control configuration.

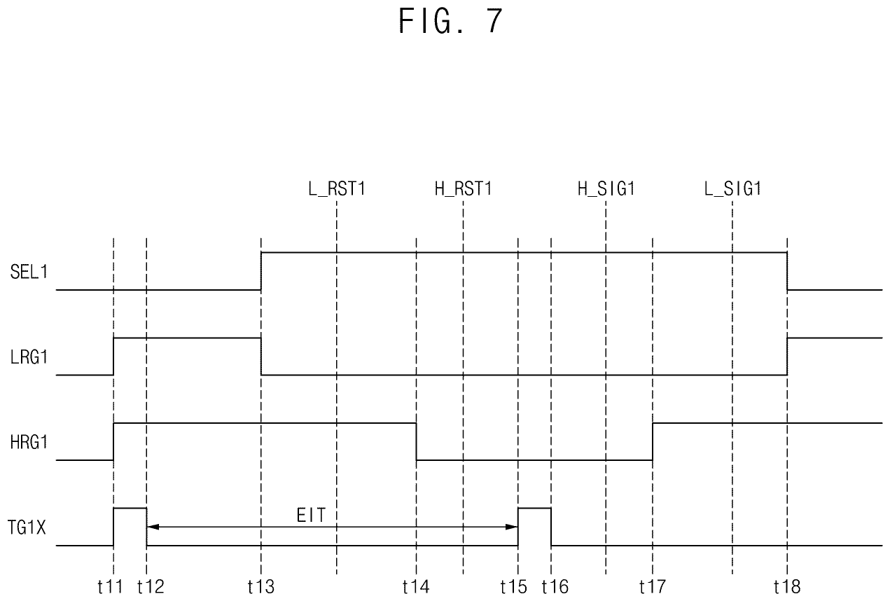

FIG. 7 is a timing diagram illustrating an operation of a first pixel of FIG. 6, according to example embodiments.

Referring to FIG. 7, an example of an operation of the first pixel 200a of FIG. 6 in the high-illuminance environment is illustrated. When each signal is at a high level, a corresponding transistor may be turned on. A transfer signal TG1X may represent at least one of the plurality of first transfer signals TG11 to TG1N in FIG. 6.

At time point t11, at least one of the plurality of first transfer transistors TX11 to TX1N, the first reset transistor RX1, and the first gain control transistor HGX1 may be turned on, and a reset operation using the pixel power supply voltage VPIX may be performed.

At time point t12, at least one of the plurality of first transfer transistors TX11 to TX1N may be turned off, and the plurality of first photodiodes PD11 to PD1N may perform the photoelectric conversion operation to collect the first photocharges. The photoelectric conversion operation may be performed until time point t15, and time period EIT may represent effective integration time.

At time point t13, the first selection transistor SELX1 may be turned on, and the first reset transistor RX1 may be turned off. At time point t14, the first gain control transistor HGX1 may be turned off. A first reset component L_RST1 may be sensed between time point t13 and time point t14, and a second reset component H_RST1 may be sensed between time point t14 and time point t15.

At time point t15, at least one of the plurality of first transfer transistors TX11 to TX1N may be turned on, and the first photocharges may be transferred to the first floating diffusion region FD1.

At time point t16, at least one of the plurality of first transfer transistors TX11 to TX1N may be turned off. At time point t17, the first gain control transistor HGX1 may be turned on. At time point t18, the first reset transistor RX1 may be turned on, and the first selection transistor SELX1 may be turned off. A first signal component H_SIG1 may be sensed between time point t16 and time point t17, and a second signal component L_SIG1 may be sensed between time point t17 and time point t18.

During the sensing operation for the first pixel 200a, the reset components L_RST1 and H_RST1 may be sensed, and then the signal components L_SIG1 and H_SIG1 may be sensed. An effective image component may be obtained based on the reset components L_RST1 and H_RST1 and the signal components L_SIG1 and H_SIG1.

In some example embodiments, in the full mode, the transfer signal TG1X may correspond to one of the plurality of first transfer signals TG11 to TG1N, and the above-described operations may be sequentially performed on the plurality of first photodiodes PD11 to PD1N. In some example embodiments, in the binning mode, the transfer signal TG1X may correspond to all of the plurality of first transfer signals TG11 to TG1N, and the above-described operations may be simultaneously performed (e.g., at substantially the same time) on all of the plurality of first photodiodes PD11 to PD1N.

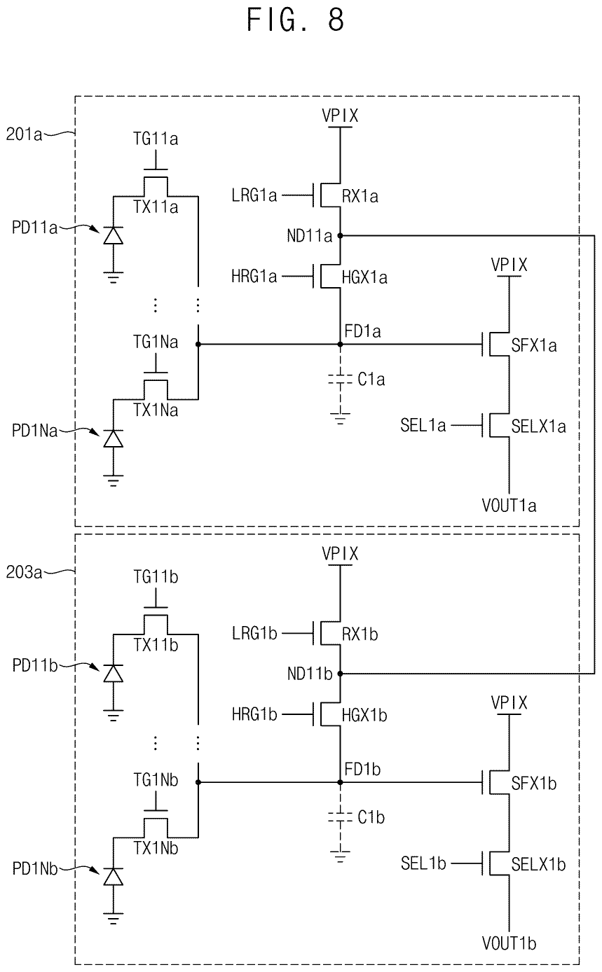

FIG. 8 is a circuit diagram illustrating an example of first pixels included in a pixel array of an image sensor, according to example embodiments. The descriptions repeated with or overlapping with descriptions of FIG. 6 may be omitted in the interest of brevity.

Referring to FIG. 8, an example of two first pixels 201a and 203a are illustrated.

Each pixel of the first pixels 201a and 203a may be similar to the first pixel 200a of FIG. 6. Components PD11a to PD1Na, FD1a, C1a, TX11a to TX1Na, RX1a, HGX1a, ND11a, SFX1a and SELX1a and related signals TG11a to TG1Na, LRG1a, HRG1a, SEL1a and VOUT1a of the first pixel 201a may be substantially similar and/or the same as the components PD11 to PD1N, FD1, C1, TX11 to TX1N, RX1, HGX1, ND11, SFX1 and SELX1 and the related signals TG11 to TG1N, LRG1, HRG1, SEL1 and VOUT1 of the first pixel 200a of FIG. 6, respectively. Components PD11b to PD1Nb, FD1b, C1b, TX11b to TX1Nb, RX1b, HGX1b, ND11b, SFX1b and SELX1b and related signals TG11b to TG1Nb, LRG1b, HRG1b, SEL1b and VOUT1b of the first pixel 203a may be substantially similar and/or the same as the components PD11 to PD1N, FD1, C1, TX11 to TX1N, RX1, HGX1, ND11, SFX1 and SELX1 and the related signals TG11 to TG1N, LRG1, HRG1, SEL1 and VOUT1 of the first pixel 200a of FIG. 6, respectively.

The nodes ND11a and ND11b of two adjacent first pixels 201a and 203a may be electrically connected to each other. In this example, the first floating diffusion region included in one of the two adjacent first pixels 201a and 203a may operate as the first gain control capacitor for the other of the two adjacent first pixels 201a and 203a.

For example, when the first pixel 201a operates, the first floating diffusion region FD1b of the first pixel 203a may operate as the first gain control capacitor for the first pixel 201a. For example, when the first pixel 203a operates, the first floating diffusion region FD1a of the first pixel 201a may operate as the first gain control capacitor for the first pixel 203a. Therefore, unlike the first pixel 200a of FIG. 6, the first gain control capacitors connected to the nodes ND11a and ND11b may be omitted in the first pixels 201a and 203a.

FIG. 9 is a circuit diagram illustrating an example of a first pixel included in a pixel array of an image sensor, according to example embodiments. The descriptions repeated with or overlapping with descriptions of FIG. 6 may be omitted in the interest of brevity.

Referring to FIG. 9, a first pixel 200b may include a plurality of first photodiodes PD11 to PD1N, a plurality of first transfer transistors TX11 to TX1N, a first floating diffusion region FD1, a first reset transistor RX1, a first gain control transistor HGX1, a second gain control transistor MGX1, a first gain control capacitor CC1, a second gain control capacitor CC2, a first driving transistor SFX1 and a first selection transistor SELX1.

The first pixel 200b may be substantially similar and/or the same as the first pixel 200a of FIG. 6, except that the first pixel 200b may further include the second gain control transistor MGX1 and the second gain control capacitor CC2.

The first reset transistor RX1, the first gain control transistor HGX1 and the second gain control transistor MGX1 may be connected in series between a pixel power supply voltage VPIX and the first floating diffusion region FD1. The second gain control transistor MGX1 may include a gate electrode receiving a first medium gain control signal MRG1.

The first gain control capacitor CC1 may be connected between a node ND11, which is between the first gain control transistor HGX1 and the second gain control transistor MGX1, and a ground voltage. The second gain control capacitor CC2 may be connected between a node ND12, which may be between the first reset transistor RX1 and the second gain control transistor MGX1, and the ground voltage.

In some example embodiments, a gain (or conversion gain) of the first pixel 200b may be adjusted using the first gain control transistor HGX1 and the second gain control transistor MGX1 by changing a capacitance of the first floating diffusion region FD1 based on the first high gain control signal HRG1 and the first medium gain control signal MRG1.

For example, in a low-illuminance environment where the illuminance of the driving environment is lower than a first reference illuminance, the first reset transistor RX1, the first gain control transistor HGX1 and the second gain control transistor MGX1 may be turned off. In this example, the capacitance of the first floating diffusion region FD1 may correspond to C1.

As another example, in a medium-illuminance environment where the illuminance of the driving environment is higher than or equal to the first reference illuminance and is lower than a second reference illuminance that is higher than the first reference illuminance, the first reset transistor RX1 and the second gain control transistor MGX1 may be turned off, and the first gain control transistor HGX1 may be turned on. In this example, as compared to the low-illuminance environment, the capacitance of the first floating diffusion region FD1 may increase by a capacitance of the first gain control capacitor CC1 (e.g., the capacitance of the first floating diffusion region FD1 may correspond to C1+CC1), and thus a relatively large amount of photocharges may be accumulated.

As another example, in a high-illuminance environment where the illuminance of the driving environment of the image sensor is higher than or equal to the second reference illuminance, the first reset transistor RX1 may be turned off, and the first gain control transistor HGX1 and the second gain control transistor MGX1 may be turned on. In this example, as compared to the medium-illuminance environment, the capacitance of the first floating diffusion region FD1 may increase by a capacitance of the second gain control capacitor CC2 (e.g., the capacitance of the first floating diffusion region FD1 may correspond to C1+CC1+CC2), and thus a larger amount of photocharges may be accumulated.

As a result, a triple conversion gain TCG may be implemented by selectively switching the first gain control transistor HGX1 and the second gain control transistor MGX1. As such, an example where one of three gains is selected using two gain control transistors may be referred to as a triple gain control configuration.

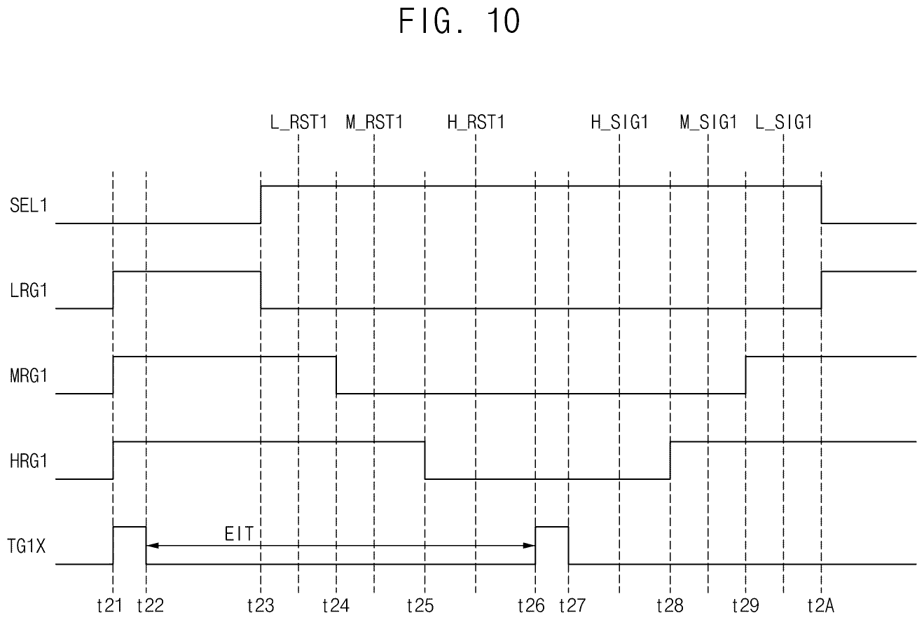

FIG. 10 is a timing diagram illustrating an operation of a first pixel of FIG. 9, according to example embodiments. The descriptions repeated with or overlapping with descriptions of FIG. 7 may be omitted in the interest of brevity.

Referring to FIG. 10, an example of an operation of the first pixel 200b of FIG. 9 in the high-illuminance environment is illustrated.

At time point t21, at least one of the plurality of first transfer transistors TX11 to TX1N, the first reset transistor RX1, the first gain control transistor HGX1 and the second gain control transistor MGX1 may be turned on, and a reset operation may be performed.

At time point t22, at least one of the plurality of first transfer transistors TX11 to TX1N may be turned off, and the plurality of first photodiodes PD11 to PD1N may perform the photoelectric conversion operation to collect the first photocharges. The photoelectric conversion operation may be performed until time point t26.

At time point t23, the first selection transistor SELX1 may be turned on and the first reset transistor RX1 may be turned off. At time point t24, the second gain control transistor MGX1 may be turned off. At time point t25, the first gain control transistor HGX1 may be turned off. A first reset component L_RST1 may be sensed between time point t23 and time point t24, a second reset component M_RST1 may be sensed between time point t24 and time point t25, and a third reset component H_RST1 may be sensed between time point t25 and time point t26.

At time point t26, at least one of the plurality of first transfer transistors TX11 to TX1N may be turned on, and the first photocharges may be transferred to the first floating diffusion region FD1.

At time point t27, at least one of the plurality of first transfer transistors TX11 to TX1N may be turned off. At time point t28, the first gain control transistor HGX1 may be turned on. At time point t29, the second gain control transistor MGX1 may be turned off. At time point t2A, the first reset transistor RX1 may be turned on, and the first selection transistor SELX1 may be turned off. A first signal component H_SIG1 may be sensed between time point t27 and time point t28, a second signal component M_SIG1 may be sensed between time point t28 and time point t29, and a third signal component L_SIG1 may be sensed between time point t29 and time point t2A.

During the sensing operation for the first pixel 200b, the reset components L_RST1, M_RST1 and H_RST1 may be sensed, and then the signal components L_SIG1, M_SIG1 and H_SIG1 may be sensed. An effective image component may be obtained based on the reset components L_RST1, M_RST1 and H_RST1 and the signal components L_SIG1, M_SIG1 and H_SIG1.

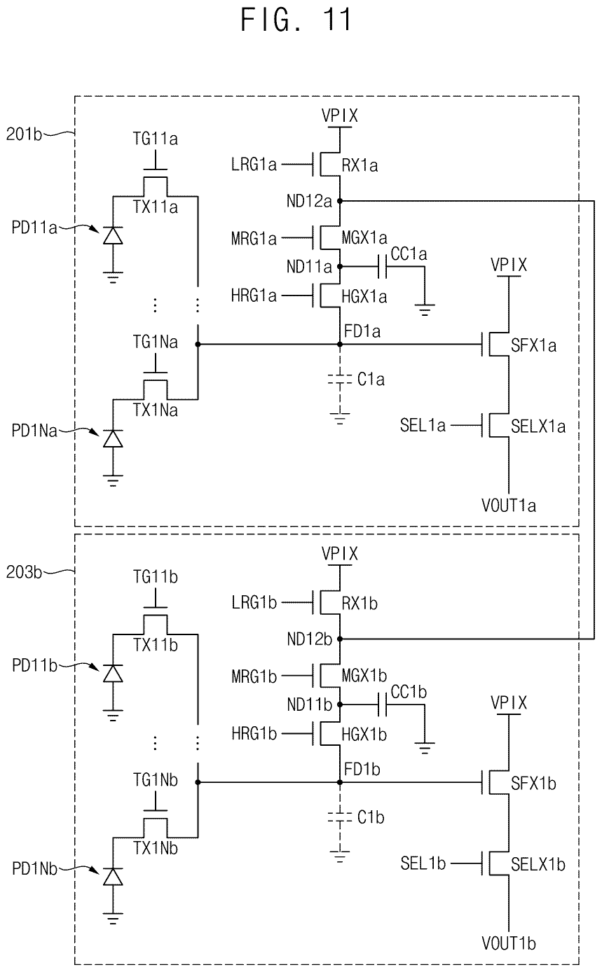

FIG. 11 is a circuit diagram illustrating an example of first pixels included in a pixel array of an image sensor, according to example embodiments. The descriptions repeated with or overlapping with descriptions of FIG. 9 may be omitted in the interest of brevity.

Referring to FIG. 11, an example of two first pixels 201b and 203b are illustrated.

Each pixel of the first pixels 201b and 203b may be similar to the first pixel 200b of FIG. 9. Components PD11a to PD1Na, FD1a, C1a, TX11a to TX1Na, RX1a, HGX1a, MGX1a, CC1a, ND11a, ND12a, SFX1a and SELX1a and related signals TG11a to TG1Na, LRG1a, HRG1a, MRG1a, SEL1a and VOUT1a of the first pixel 201b may be substantially similar and/or the same as the components PD11 to PD1N, FD1, C1, TX11 to TX1N, RX1, HGX1, MGX1, CC1, ND11, ND12, SFX1 and SELX1 and the related signals TG11 to TG1N, LRG1, HRG1, MRG1, SEL1 and VOUT1 of the first pixel 200b of FIG. 9, respectively. Components PD11a to PD1Na, FD1a, C1a, TX11a to TX1Na, RX1a, HGX1a, MGX1a, CC1a, ND11a, ND12a, SFX1a and SELX1a and related signals TG11a to TG1Na, LRG1a, HRG1a, MRG1a, SEL1a and VOUT1a of the first pixel 201b may be substantially similar and/or the same as the components PD11 to PD1N, FD1, C1, TX11 to TX1N, RX1, HGX1, MGX1, CC1, ND11, ND12, SFX1 and SELX1 and the related signals TG11 to TG1N, LRG1, HRG1, MRG1, SEL1 and VOUT1 of the first pixel 200b of FIG. 9, respectively.

The nodes ND12a and ND12b of two adjacent first pixels 201b and 203b may be electrically connected to each other. In this example, at least one of the first gain control capacitor and the first floating diffusion region included in one of the two adjacent first pixels 201b and 203b may operate as the second gain control capacitor for the other of the two adjacent first pixels 201b and 203b.

For example, when the first pixel 201b operates, at least one of the first floating diffusion region FD1b and the first gain control capacitor CC1b of the first pixel 203b may operate as the second gain control capacitor for the first pixel 201b. As another example, when the first pixel 203b operates, at least one of the first floating diffusion region FD1a and the first gain control capacitor CC1a of the first pixel 201b may operate as the second gain control capacitor for the first pixel 203b. Therefore, unlike the first pixel 200b of FIG. 9, the second gain control capacitors connected to the nodes ND12a and ND12b may be omitted in the first pixels 201b and 203b.

However, example embodiments are not limited to the above-described configurations. For example, each first pixel of the plurality of first pixels PX1 may include an arbitrary number of gain control transistors and an arbitrary number of gain control capacitors, and the number of gain control capacitors in each first pixel may be smaller than or equal to the number of gain control transistors in each first pixel.

FIG. 12 is a circuit diagram illustrating an example of a second pixel included in a pixel array of an image sensor, according to example embodiments.

Referring to FIG. 12, a second pixel 300a may include a plurality of second photodiodes (e.g., a first photodiode PD21, a second photodiode PD22, to an N-th photodiode PD2N), a plurality of second transfer transistors (e.g., a first transfer transistor TX21, a second transfer transistor TX22, to an N-th transfer transistor TX2N), a second floating diffusion region FD2, a second reset transistor RX2, a lateral overflow integration capacitor LC, a discharge transistor DX, a second driving transistor SFX2, and a second selection transistor SELX2.

The plurality of second photodiodes PD21 to PD2N, the second floating diffusion region FD2 and the lateral overflow integration capacitor LC may be substantially similar and/or the same as the plurality of second photodiodes PD2, the second floating diffusion region FD2 and the lateral overflow integration capacitor LC in FIG. 1, respectively.

The plurality of second transfer transistors TX21 to TX2N may be connected between the plurality of second photodiodes PD21 to PD2N and the second floating diffusion region FD2, respectively. Each transfer transistor of the plurality of second transfer transistors TX21 to TX2N may include a gate electrode receiving a respective one of the plurality of second transfer signals (e.g., a first transfer signal TG21, a second transfer signal TG22, to an N-th transfer signal TG2N).

The second reset transistor RX2 may be connected between a reset power supply voltage VRD and the second floating diffusion region FD2, and may include a gate electrode receiving a second reset signal RG2.

The lateral overflow integration capacitor LC may be connected between a capacitor power supply voltage VMIM and the second floating diffusion region FD2, and may be directly connected to the second floating diffusion region FD2.

The discharge transistor DX may be connected between the second reset transistor RX2 and the lateral overflow integration capacitor LC, and may include a gate electrode receiving a discharge control signal (DSW).

The second driving transistor SFX2 and the second selection transistor SELX2 may be connected in series between a pixel power supply voltage VPIX and a second output terminal providing a second output voltage VOUT2. The second driving transistor SFX1 may include a gate electrode connected to the second floating diffusion region FD2, and the second selection transistor SELX2 may include a gate electrode receiving a second selection signal SEL2.

The second photocharges generated from the plurality of second photodiodes PD21 to PD2N may be transferred to the second floating diffusion region FD2 through the plurality of second transfer transistors TX21 to TX2N. The second floating diffusion region FD2, the lateral overflow integration capacitor LC, or the like, may be initialized by the second reset transistor RX2. The discharge transistor DX may assist to initialize the lateral overflow integration capacitor LC. The second driving transistor SFX2 may operate as a source follower buffer amplifier to amplify a signal corresponding to the second photocharges accumulated in the second floating diffusion region FD2. The second pixel 300a may be selected based on the second selection transistor SELX2, and amplified signal (e.g., the second output voltage VOUT2) may be provided to a column line.

In some example embodiments, both the reset power supply voltage VRD and the capacitor power supply voltage VMIM may have voltage levels substantially similar and/or the same as that of the pixel power supply voltage VPIX. In other example embodiments, at least one of the reset power supply voltage VRD and the capacitor power supply voltage VMIM may have a voltage level different from that of the pixel power supply voltage VPIX.

The second photocharges may be accumulated by a capacitance (e.g., C2) of the second floating diffusion region FD2, and overflowed photocharges among the second photocharges may be additionally accumulated in the lateral overflow integration capacitor LC.

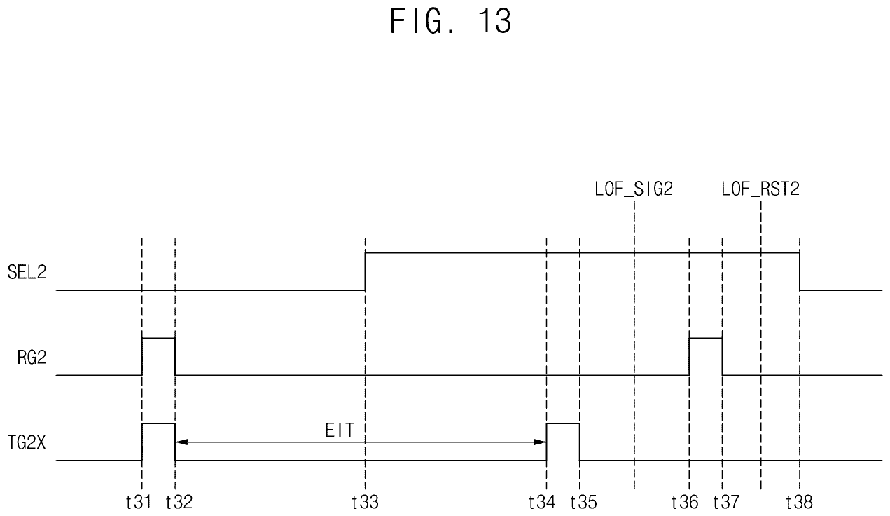

FIG. 13 is a timing diagram illustrating an operation of a second pixel of FIG. 12, according to example embodiments.

Referring to FIG. 13, an example of an operation of the second pixel 300a of FIG. 12 is illustrated. A transfer signal TG2X may represent at least one of the plurality of second transfer signals TG21 to TG2N in FIG. 12.

At time point t31, at least one of the plurality of second transfer transistors TX21 to TX2N and the second reset transistor RX2 may be turned on, and a reset operation using the reset power supply voltage VRD may be performed.

At time point t32, at least one of the plurality of second transfer transistors TX21 to TX2N may be turned off, and the plurality of second photodiodes PD21 to PD2N may perform the photoelectric conversion operation to collect the second photocharges. The photoelectric conversion operation may be performed until time point t34. In addition, the overflowed photocharges among the second photocharges may be accumulated in the lateral overflow integration capacitor LC.

At time point t33, the second selection transistor SELX2 may be turned on. At time point t34, at least one of the plurality of second transfer transistors TX21 to TX2N may be turned on, and the second photocharges may be transferred to the second floating diffusion region FD2.

At time point t35, at least one of the plurality of second transfer transistors TX21 to TX2N may be turned off. At time point t36, the second reset transistor RX2 may be turned on, and the reset operation may be performed. At time point t37, the second reset transistor RX2 may be turned off. At time point t38, the second selection transistor SELX2 may be turned off. A first signal component LOF_SIG2 may be sensed between time point t35 and time point t36, and a first reset component LOF_RST2 may be sensed between time point t37 and time point t38.

During the sensing operation for the second pixel 300a, the signal component LOF_SIG2 may be sensed, and then the reset component LOF_RST2 may be sensed because the overflowed photocharges may be needed. Thus, unlike the first pixel which may sense the reset component first and the signal component later, the signal component LOF_SIG2 may be sensed first and the reset component LOF_RST2 may be sensed later in the second pixel. An effective image component may be obtained based on the reset component LOF_RST2 and the signal component LOF_SIG2.

In some example embodiments, in the full mode, the transfer signal TG2X may correspond to one of the plurality of second transfer signals TG21 to TG2N, and the above-described operations may be sequentially performed on the plurality of second photodiodes PD21 to PD2N. In some example embodiments, in the binning mode, the transfer signal TG2X may correspond to all of the plurality of second transfer signals TG21 to TG2N, and the above-described operations may be simultaneously performed (e.g., at substantially the same time) on all of the plurality of second photodiodes PD21 to PD2N.

FIG. 14 is a circuit diagram illustrating an example of a second pixel included in a pixel array of an image sensor, according to example embodiments. The descriptions repeated with or overlapping with descriptions of FIG. 12 may be omitted in the interest of brevity.

Referring to FIG. 14, a second pixel 300b may include a plurality of second photodiodes PD21 to PD2N, a plurality of second transfer transistors TX21 to TX2N, a second floating diffusion region FD2, a second reset transistor RX2, a lateral overflow integration capacitor LC, a third gain control transistor HGX2, a discharge transistor DX, a second driving transistor SFX2 and a second selection transistor SELX2.

The second pixel 300b may be substantially similar and/or the same as the second pixel 300a of FIG. 12, except that the second pixel 300b may further include the third gain control transistor HGX2.

The second reset transistor RX2 and the third gain control transistor HGX2 may be connected in series between a reset power supply voltage VRD and the second floating diffusion region FD2. The second reset transistor RX2 may include a gate electrode receiving a second reset signal LRG2, and the third gain control transistor HGX2 may include a gate electrode receiving a second high gain control signal HRG2.

In some example embodiments, a gain (or conversion gain) of the second pixel 300b may be adjusted using the third gain control transistor HGX2 by changing a capacitance of the second floating diffusion region FD2 based on the second high gain control signal HRG2.

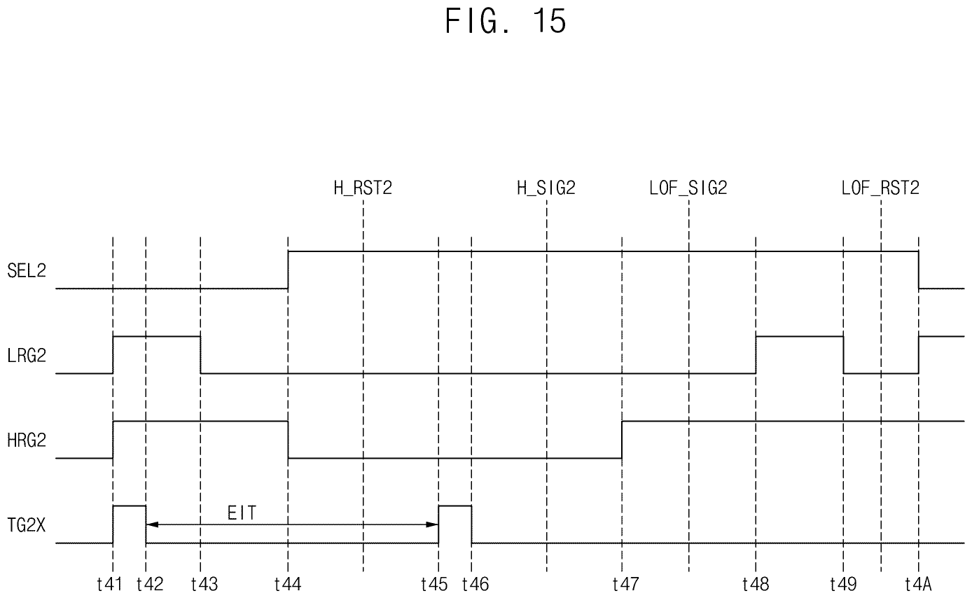

FIG. 15 is a timing diagram illustrating an operation of a second pixel of FIG. 14, according to example embodiments. The descriptions repeated with or overlapping with descriptions of FIG. 13 may be omitted in the interest of brevity.

Referring to FIG. 15, an example of an operation of the second pixel 300b of FIG. 14 is illustrated.

At time point t41, at least one of the plurality of second transfer transistors TX21 to TX2N, the second reset transistor RX2 and the third gain control transistor HGX2 may be turned on, and a reset operation may be performed.

At time point t42, at least one of the plurality of second transfer transistors TX21 to TX2N may be turned off, and the plurality of second photodiodes PD21 to PD2N may perform the photoelectric conversion operation to collect the second photocharges. The photoelectric conversion operation may be performed until time point t45.

At time point t43, the second reset transistor RX2 may be turned off. At time point t44, the second selection transistor SELX2 may be turned on, and the third gain control transistor HGX2 may be turned off. A first reset component H_RST2 may be sensed between time point t44 and time point t45.

At time point t45, at least one of the plurality of second transfer transistors TX21 to TX2N may be turned on, and the second photocharges may be transferred to the second floating diffusion region FD2.

At time point t46, at least one of the plurality of second transfer transistors TX21 to TX2N may be turned off. A first signal component H_SIG2 may be sensed between time point t46 and time point t47.

At time point t47, the third gain control transistor HGX2 may be turned on. At time point t48, the second reset transistor RX2 may be turned on, and the reset operation may be performed. At time point t49, the second reset transistor RX2 may be turned off. At time t4A, the second selection transistor SELX2 may be turned off. A second signal component LOF_SIG2 may be sensed between time point t47 and time point t48, and a second reset component LOF_RST2 may be sensed between time point t49 and time point t4A.

During the sensing operation for the second pixel 300a, the reset component H_RST2 may be sensed, and then the signal component H_SIG2 may be sensed. In addition, the signal component LOF_SIG2 may be sensed, and then the reset component (LOF_RST2) may be sensed. The operation, according to the dual gain control configuration, may be applied to the reset component H_RST2 and the signal component H_SIG2, and the operation, according to the LOFIC configuration, may be applied to the signal component LOF_SIG2 and the reset component LOF_RST2. An effective image component may be obtained based on the reset components H_RST2 and LOF_RST2 and the signal components H_SIG2 and LOF_SIG2.

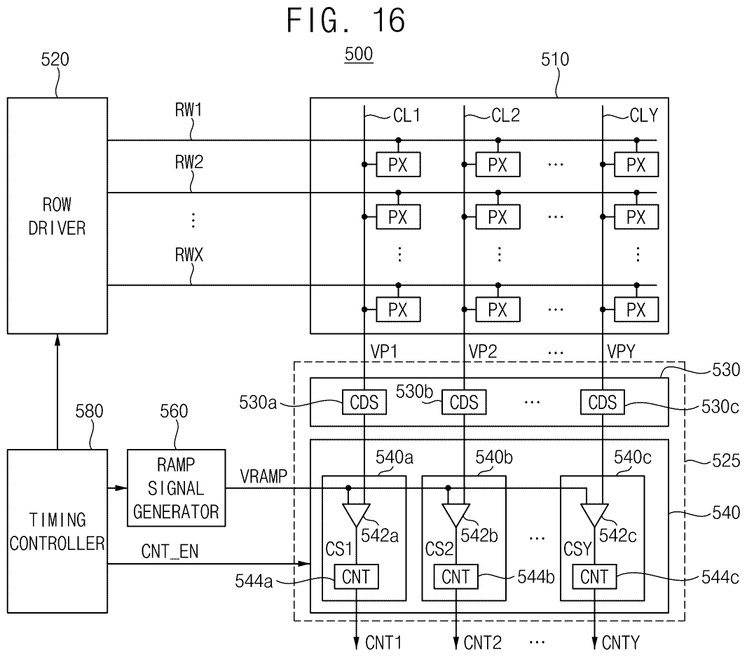

FIG. 16 is a block diagram illustrating an image sensor, according to example embodiments.

Referring to FIG. 16, an image sensor 500 may include a pixel array 510, a row driver 520 and a readout block 525. The image sensor 500 may further include a ramp signal generator 560 and a timing controller 580.

The pixel array 510 may include a plurality of pixels (or unit pixels) PX that are arranged in a matrix formation. Each pixel of the plurality of pixels PX may be connected to a respective one of a plurality of rows (e.g., a first row RW1, a second row RW2, to an X-th row RWX, where X is a positive integer greater than one (1)), and a respective one of a plurality of columns (e.g., a first column CL1, a second column CL2, to a Y-th column CLY, where Y is a positive integer greater than one (1)). The pixel array 510 may generate a plurality of pixel signals (e.g., a first pixel signal VP1, a second pixel signal VP2, to a Y-th pixel signal VPY) based on incident light. For example, the plurality of pixel signals VP1 to VPY may be and/or may include analog signals.

The pixel array 510 may be the pixel array, according to example embodiments, described with reference to FIGS. 1, 2, 3A, 3B, 3C, 4A, 4B, 5A, 5B, 5C, and 6 to 15. For example, the pixel array 510 may include the plurality of first pixels PX1 having the floating diffusion region shared configuration and the multi-gain control configuration, and may include the plurality of second pixels PX2 having the floating diffusion region shared configuration and the LOFIC configuration. The pixel array 510 may achieve both the prevention and/or reduction of the image quality deterioration potentially caused by the SNR dip phenomenon and the high dynamic range. In addition, the modification of the pixel layout may be unnecessary, the pixel configuration may be simplified, and thus the development difficulty and cost may be reduced, when compared to a related image sensor. Further, the operating speed may be improved and power consumption may be reduced during the operation of the image sensor 500.

The row driver 520 may be connected to the plurality of rows RW1 to RWX of the pixel array 510. The row driver 520 may generate driving signals to drive the plurality of rows RW1 to RWX. For example, the row driver 520 may drive the plurality of pixels PX included in the pixel array 510 by units of rows (or row by row).

The readout block 525 may perform a sensing operation and/or a readout operation based on the plurality of pixel signals VP1 to VPY output from the pixel array 510 driven by units of rows, and generates a plurality of output signals (e.g., a first output signal CNT1, a second output signal CNT2, to a Y-th output signal CNTY). For example, the plurality of output signals CNT1 to CNTY may be and/or may include digital signals. That is, the readout block 525 may perform an analog-to-digital conversion (ADC) operation.

The readout block 525 may include a correlated double sampling (CDS) block 530 and an analog-to-digital conversion block 540.

The correlated double sampling block 530 may include a plurality of correlated double sampling circuits (CDSs) (e.g., a first CDS 530a, a second CDS 530b, to a c-th CDS 530c, where c is a positive integer greater than one (1)). The plurality of correlated double sampling circuits 530a to 530c may be connected to the plurality of columns CL1 to CLY of the pixel array 510. The plurality of correlated double sampling circuits 530a to 530c may perform a correlated double sampling operation on the plurality of pixel signals VP1 to VPY output from the pixel array 510.

The analog-to-digital conversion block 540 may include a plurality of analog-to-digital converters (ADCs) (e.g., a first ADC 540a, a second ADC 540b, to a c-th ADC 540c). The plurality of analog-to-digital converters 540a to 540c may be connected to the plurality of columns CL1 to CLY of the pixel array 510 via the plurality of correlated double sampling circuits 530a to 530c. The plurality of analog-to-digital converters 540a to 540c may perform a column analog-to-digital conversion operation that may convert the plurality of pixel signals VP1 to VPY (e.g., a plurality of correlated double sampled pixel signals output from the plurality of correlated double sampling circuits 530a to 530c) into the plurality of output signals CNT1 to CNTY in parallel (e.g., simultaneously and/or concurrently).

Each analog-to-digital converter of the plurality of analog-to-digital converters 540a to 540c may include a respective one of a plurality of comparators (e.g., a first comparator 542a, a second comparator 542b, to a c-th comparator 542c) and a respective one of a plurality of counters (CNTs) (e.g., a first counter 544a, a second counter 544b, to a c-th counter 544c). For example, the first analog-to-digital converter 540a may include the first comparator 542a and the first counter 544a. The first comparator 542a may compare the first pixel signal VP1 (e.g., the correlated double sampled first pixel signal output from the first correlated double sampling circuit 530a) with a ramp signal VRAMP to generate a first comparison signal CS1. The first counter 544a may count a level transition timing of the first comparison signal CS1 to generate the first output signal CNT1.

Operations of the correlated double sampling block 530 and the analog-to-digital conversion block 540 may be performed on the plurality of pixels PX included in the pixel array 510 by units of rows (or row by row).

The plurality of correlated double sampling circuits 530a to 530c and the plurality of analog-to-digital converters 540a to 540c may form a plurality of column driving circuits. For example, the first correlated double sampling circuit 530a and the first analog-to-digital converter 540a may form a first column driving circuit.

The ramp signal generator 560 may generate the ramp signal VRAMP. The timing controller 580 may control overall operation timings of the image sensor 500, and may generate control signals including a count enable signal CNT_EN, a clock signal, or the like.

In some example embodiments, the plurality of output signals CNT1 to CNTY may be provided to an external processor (e.g., an image signal processor (ISP) and/or an application processor (AP)). The external processor may perform an image processing operation based on the plurality of output signals CNT1 to CNTY, and may additionally perform an image compensating (or correcting) operation.

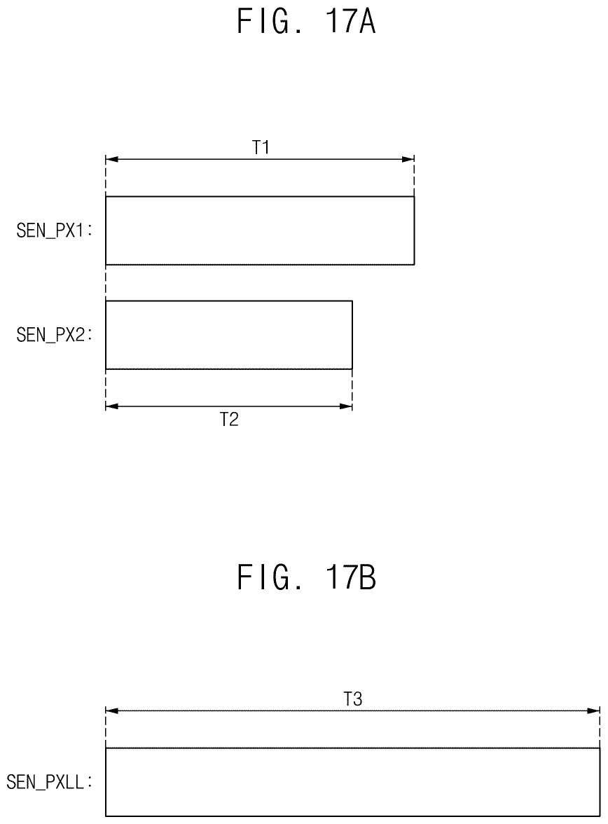

FIGS. 17A and 17B are diagrams illustrating an operation of an image sensor, according to example embodiments.

Referring to FIGS. 16 and 17A, an example of an operation of the image sensor 500 including the plurality of first pixels PX1 and the plurality of second pixels PX2, according to example embodiments, is illustrated.

Among the plurality of pixel signals VP1 to VPY generated from the plurality of first pixels PX1 and the plurality of second pixels PX2 included in the pixel array 510, a first pixel signal and a second pixel signal, which may be generated from one first pixel (e.g., a first-first pixel) and one second pixel (e.g., a second-first pixel) that may be arranged in the same row (e.g., a first row), may be simultaneously (e.g., at substantially the same time) output and provided to the readout block 525.

The readout block 525 may simultaneously perform (e.g., at substantially the same time) sensing operations on the first pixel signal and the second pixel signal. For example, a sensing operation SEN_PX1 for the first pixel signal and a sensing operation SEN_PX2 for the first pixel signal may be started simultaneously (e.g., at substantially the same time).

The readout block 525 may sense the first pixel signal during a first time interval T1 based on a first operation timing. For example, the first operation timing may be associated with or related to the multi-gain control configuration, and may include an operation of sensing a reset component first and a signal component later.

In some example embodiments, the first operation timing may be changed depending on the configuration of the first pixel PX1. For example, when the first pixel PX1 has the configuration illustrated in FIG. 6, the first operation timing may correspond to the operation described with reference to FIG. 7. For example, when the first pixel PX1 has the configuration illustrated in FIG. 9, the first operation timing may correspond to the operation described with reference to FIG. 10.

The readout block 525 may sense the second pixel signal during a second time interval T2 based on a second operation timing that is different from the first operation timing. For example, the second operation timing may be associated with or related to the LOFIC configuration, and may include an operation of sensing a signal component first and a reset component later to sense overflowed photocharges.

In some example embodiments, the second operation timing may be changed depending on the configuration of the second pixel PX2. For example, when the second pixel PX2 has the configuration illustrated in FIG. 12, the second operation timing may correspond to the operation described with reference to FIG. 13. As another example, when the second pixel PX2 has the configuration illustrated in FIG. 14, the second operation timing may correspond to the operation described with reference to FIG. 15.

When the pixel array 510 including the first pixels PX1 and the second pixels PX2, according to example embodiments, is implemented, the sensing time for one row may correspond to a longer one of the first time interval T1 and the second time interval T2. Although FIG. 17A illustrates an example where the first time interval T1 is longer than the second time interval T2, example embodiments are not limited thereto.

Referring to FIG. 17B, an example of an operation of an image sensor in which all pixels have the multi-gain control configuration and the LOFIC configuration is illustrated, and an example of a sensing operation SEN_PXLL for a third pixel signal generated from a pixel arranged in one row is illustrated.

For example, the third pixel signal may be sensed during a third time interval T3 based on a third operation timing that is different from the first and second operation timings. For example, the third operation timing may be associated with or related to both the multi-gain control configuration and the LOFIC configuration. Since operations for both the multi-gain control configuration and the LOFIC configuration may be performed, the third time interval T3 may be longer than the first time interval T1 and the second time interval T2.

As illustrated in FIGS. 17A and 17B, when the pixel array 510 including the first pixels PX1 and the second pixels PX2, according to example embodiments, is implemented, the time for the sensing operation for one row may be reduced, thereby improving the operating speed and reducing the power consumption.

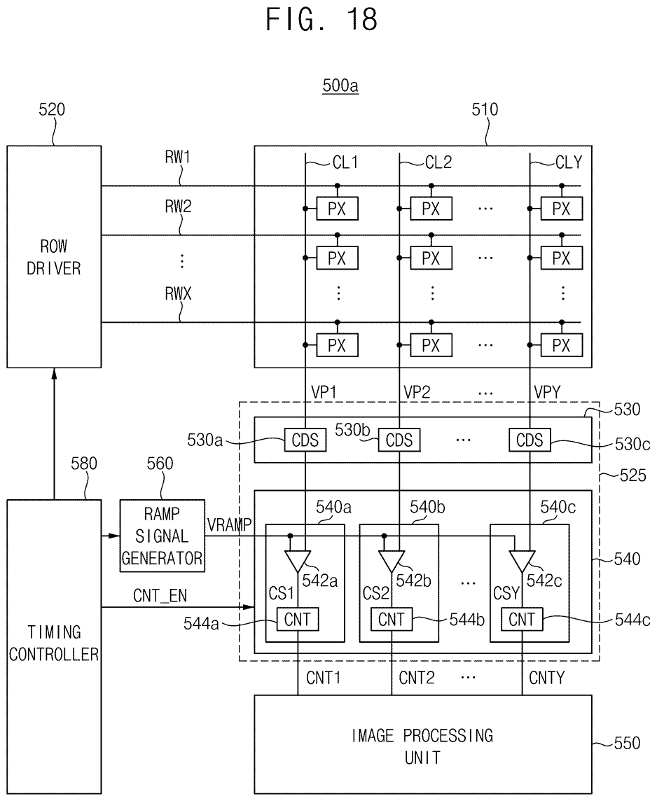

FIG. 18 is a block diagram illustrating an image sensor, according to example embodiments. The descriptions repeated with or overlapping with descriptions of FIG. 16 may be omitted in the interest of brevity.

Referring to FIG. 18, an image sensor 500a may include a pixel array 510, a row driver 520 and a readout block 525. The image sensor 500a may further include an image processing unit 550, a ramp signal generator 560 and a timing controller 580.

The image sensor 500a may be substantially similar and/or the same as the image sensor 500 of FIG. 16, except that the image sensor 500a may further include the image processing unit 550.

The image processing unit 550 may perform an image processing operation based on the plurality of output signals CNT1 to CNTY. For example, the image processing unit 550 may generate a single image signal by synthesizing the plurality of output signals CNT1 to CNTY.

In an embodiment, the image processing unit 550 may be physically implemented by analog and/or digital circuits including one or more of a logic gate, an integrated circuit, a microprocessor, a microcontroller, a memory circuit, a passive electronic component, an active electronic component, an optical component, and the like. For example, a field programmable gate array (FPGA) may be used to implement custom logic that may include the functionality of the image processing unit 550. As another example, a processor in combination with a memory may be used to execute one or more instructions to perform the functionality of the image processing unit 550. Alternatively or additionally, at least a portion of the functionality of image processing unit 550 may be incorporated into an external processor and/or implemented as instructions to be executed by an external processor.

In some example embodiments, the image processing unit 550 may further perform an image compensating operation using output signals generated by the plurality of second pixels PX2 among the plurality of output signals CNT1 to CNTY. For example, the image processing unit 550 may perform a brightness adjustment operation and/or a dynamic range enhancement operation on one image signal based on the output signals generated by the plurality of second pixels PX2.

In some example embodiments, the image processing unit 550 may perform the image compensating operation when the number of the plurality of second pixels PX2 is smaller than the number of the plurality of first pixels PX1. That is, the image compensating operation may be performed only when the number of the plurality of second pixels PX2 may be relatively small.

In some example embodiments, when the image sensor does not include the image processing unit 550 (e.g., in the image sensor 500 of FIG. 16) the image processing operation and/or the image compensating operation may be performed by the external processor.

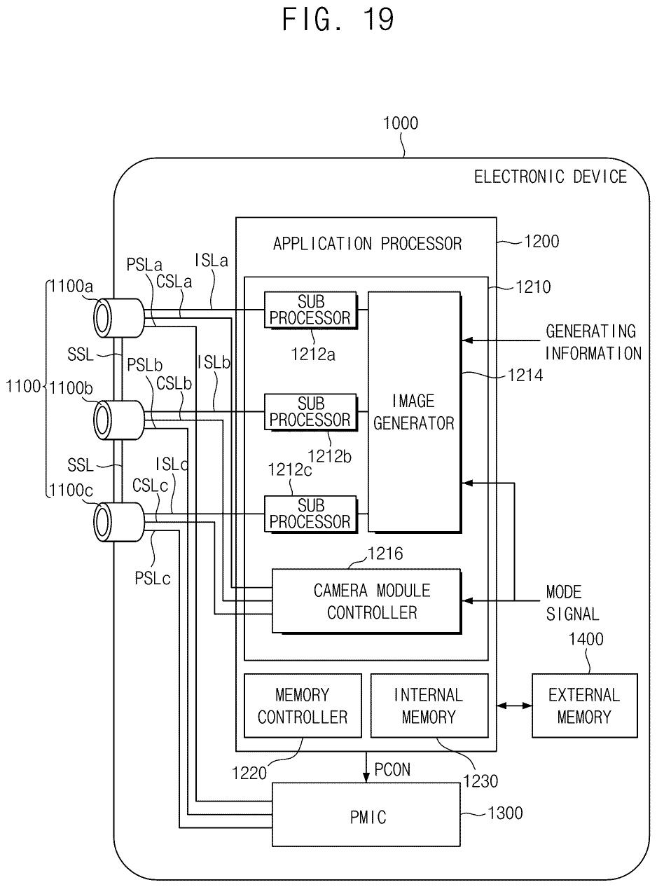

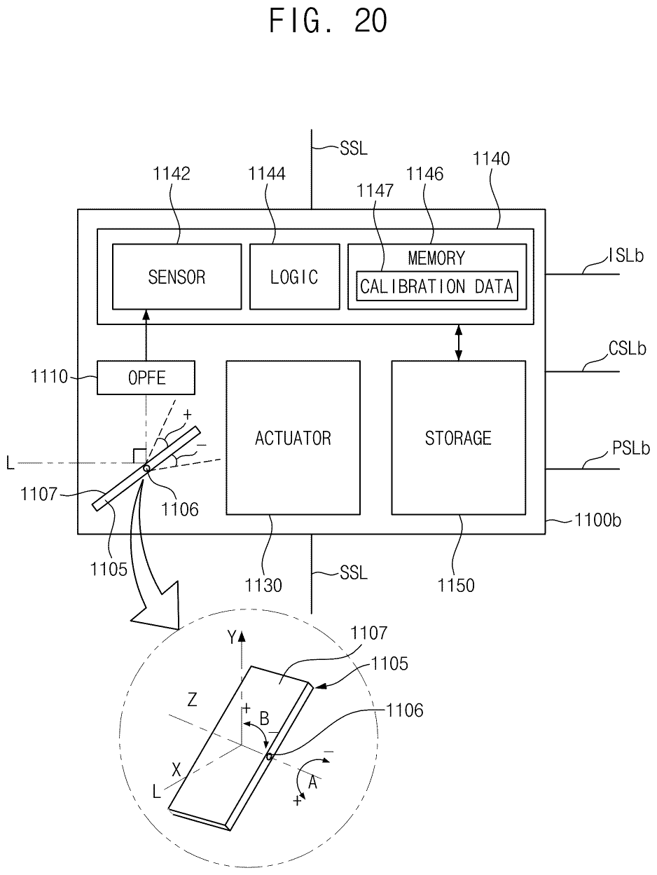

FIG. 19 is a block diagram illustrating an electronic device, according to example embodiments. FIG. 20 is a block diagram illustrating an example of a camera module included in an electronic device of FIG. 19.

Referring to FIG. 19, an electronic device 1000 may include a camera module group 1100, an application processor 1200, a power management integrated circuit (PMIC) 1300, and an external memory 1400.

The camera module group 1100 may include a plurality of camera modules (e.g., a first camera module 1100a, a second camera module 1100b, and a third camera module 1100c). Although FIG. 19 illustrates the three (3) camera modules 1100a, 1100b and 1100c as an example, example embodiments are not limited to a particular number of camera modules. According to example embodiments, the camera module group 1100 may include two (2) camera modules, four (4) or more camera modules.

Hereinafter, an example configuration of the second camera module 1100b is described with reference to FIG. 20. According to example embodiments, the same descriptions may be applied to the other camera modules (e.g., the first camera module 1100a and third camera module 1100c).

Referring to FIG. 20, the second camera module 1100b may include a prism 1105, an optical path folding element (OPFE) 1110, an actuator 1130, an image sensing device 1140, and a storage device 1150.

The prism 1105 may include a reflection surface 1107 to change a path of a light L incident on the prism 1105.

In some example embodiments, the prism 1105 may change the path of the light L incident in a first direction X to a path in a second direction Y perpendicular to the first direction X. In addition, the prism 1105 may rotate the reflection surface 1107 around a center axis 1106 and/or rotate the center axis 1106 in a direction B to align the path of the reflected light along the second direction Y. In addition, the OPFE 1110 may move in a third direction perpendicular to the first direction X and the second direction Y.

The OPFE 1110 may include optical lenses that may be divided into m groups, where m is a positive integer greater than zero (0). The m lens group may move in the second direction Y to change an optical zoom ratio of the camera module 1100b. For example, the optical zoom ratio may be changed in a range of 3K, 5K, or the like by moving the m lens group, when K is a basic optical zoom ratio of the second camera module 1100b.

The actuator 1130 may move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144, and a memory 1146. The image sensor 1142 may capture or sense an image using the light L provided through the optical lens. The control logic 1144 may control overall operations of the second camera module 1100b. For example, the control logic 1144 may provide control signals through control signal line CSLb to control the operation of the second camera module 1100b.

The memory 1146 may store information such as calibration data 1147 for the operation of the second camera module 1100b. For example, the calibration data 1147 may include information for generation of image data based on the provided light, such as information on the above-described rotation angle, a focal length, information on an optical axis, and so on. When the second camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. For example, the storage device 1150 may be disposed outside of the image sensing device 1140, and the storage device 1150 may be stacked with a sensor chip comprising the image sensing device 1140. For example, the storage device 1150 may be implemented with an electrically erasable programmable read-only memory (EEPROM). However, example embodiments are not limited thereto.

In some example embodiments, each camera module of the plurality of camera modules 1100a to 1100c may include the actuator 1130. In some example embodiments, the plurality of camera modules 1100a to 1100c may include substantially similar and/or the same or different calibration data 1147 depending on the operations of the actuators 1130.

In some example embodiments, at least one camera module (e.g., the second camera module 1100b) may have a folded lens structure included the above-described prism 1105 and the OPFE 1110, and the other camera modules (e.g., the first camera module 1100a and the third camera module 1100c) may have a vertical structure without the prism 1105 and the OPFE 1110.

In some example embodiments, at least one camera module (e.g., the third camera module 1100c) may be a depth camera configured to measure distance information of an object using an infrared light. In some example embodiments, the application processor 1200 may merge the distance information provided from the depth camera 1100c and image data provided from the other camera modules (e.g., the first camera module 1100a and the second camera module 1100b) to generate a three-dimensional depth image.

In some example embodiments, at least two camera modules from among the plurality of camera modules 1100a to 1100c may have different field of views, for example, through different optical lenses.

In some example embodiments, each camera module of the plurality of camera modules 1100a to 1100c may be separated physically from each other. That is, the plurality of camera modules 1100a to 1100c may each include a dedicated image sensor 1142.

Referring again to FIG. 19, the application processor 1200 may include an image processing device 1210, a memory controller 1220, and an internal memory 1230. The application processor 1200 may be separated from the plurality of camera modules 1100a to 1100c. For example, the application processor 1200 may be implemented as one chip and the plurality of camera modules 1100a to 1100c may implemented as another chip and/or other chips.

The image processing device 1210 may include a plurality of sub-processors (e.g., a first sub-processor 1212a, a second sub-processor 1212b, and a third sub-processor 1212c), an image generator 1214, and a camera module controller 1216.

The image data generated by the plurality of camera modules 1100a to 1100c may be provided to the first to third sub-processors 1212a to 1212c through distinct image signal lines (e.g., a first image signal line ISLa, a second image signal line ISLb, and a third image signal line ISLc), respectively. For example, the transfer of the image data may be performed using a camera serial interface (CSI) based on the mobile industry processor interface (MIPI), but example embodiments are not limited thereto.

In some example embodiments, one sub-processor may be assigned commonly to two or more camera modules. In some example embodiments, a multiplexer may be used to transfer the image data selectively from one of the camera modules to the shared sub-processor.

The image data from the first to third sub-processors 1212a to 1212c may be provided to the image generator 1214. The image generator 1214 may generate an output image using the image data from the sub-processors first to third 1212a to 1212c based on image generating information or a mode signal. For example, the image generator 1214 may merge at least a portion of the image data from the plurality of camera modules 1100a to 1100c having the different fields of view to generate the output image based on the image generating information or the mode signal. In addition, the image generator 1214 may select, as the output image, one of the image data from the plurality of camera modules 1100a to 1100c based on the image generating information or the mode signal.

In some example embodiments, the image generating information may include a zoom factor or a zoom signal. In some example embodiments, the mode signal may be and/or may include a signal based on a selection of a user.

In some example embodiments, the image generator 1214 may receive the image data of different exposure times from the plurality of camera modules 1100a to 1100c. In some example embodiments, the image generator 1214 may perform high dynamic range (HDR) processing with respect to the image data from the plurality of camera modules 1100a to 1100c to generate the output image having the increased dynamic range.

The camera module controller 1216 may provide control signals to the plurality of camera modules 1100a to 1100c. The control signals generated by the camera module controller 1216 may be provided to the plurality of camera modules 1100a 1100c through distinct control signal lines (e.g., a first control signal line CSLa, a second control signal line CSLb, and a third control signal line CSLc), respectively.

In some example embodiments, at least one of the plurality of camera modules 1100a to 1100c may be designated as a master camera based on the image generating information of the mode signal, and the other camera modules may be designated as slave cameras.

The camera module operating as the master camera may be changed based on the zoom factor or an operation mode signal. For example, when the first camera module 1100a has the wider field of view than the second camera module 1100b and the zoom factor indicates a lower zoom magnification, the second camera module 1100b may be designated as the master camera. Alternatively or additionally, when the zoom factor indicates a higher zoom magnification, the first camera module 1100a may be designated as the master camera.

In some example embodiments, the control signals provided from the camera module controller 1216 may include a synch enable signal. For example, when the second camera module 1100b is the master camera and the first and third camera modules 1100a and 1100c are the slave cameras, the camera module controller 1216 may provide the synch enable signal to the second camera module 1100b. The second camera module 1100b may generate a synch signal based on the provided synch enable signal and provide the synch signal to the first and third camera modules 1100a and 1100c through a synch signal line SSL. As such, the plurality of camera modules 1100a to 1100c may transfer the synchronized image data to the application processor 1200 based on the synch signal.

The PMIC 1300 may provide a power supply voltage to the plurality of camera modules 1100a to 1100c, respectively. For example, the PMIC 1300 may provide, under control of the application processor 1200, a first power to the first camera module 1100a through a first power line PSLa, a second power to the second camera module 1100b through a second power line PSLb, and a third power to the third camera module 1100c through a third power line PSLc.

The example embodiments may be applied to various electronic devices and systems that may include the image sensors. For example, the example embodiments may be applied to systems such as, but not limited to, a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an Internet of Things (IoT) device, an Internet of Everything (IoE) device, an e-book reader, a virtual reality (VR) device, an augmented reality (AR) device, a robotic device, a drone, an automotive, or the like.

The foregoing is illustrative of example embodiments and is not to be construed as limiting thereof. Although some example embodiments have been described, those skilled in the art may readily appreciate that many modifications may be possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A pixel array of an image sensor comprising:
a plurality of first pixels, each first pixel of the plurality of first pixels comprising:
a plurality of first photodiodes configured to generate first photocharges based on incident light;
a first floating diffusion region configured to accumulate the first photocharges, the first floating diffusion region being shared by the plurality of first photodiodes;
a first reset transistor and at least one gain control transistor coupled in series between a pixel power supply voltage and the first floating diffusion region; and
at least one gain control capacitor coupled with a ground voltage and coupled between the first reset transistor and the at least one gain control transistor, the at least one gain control capacitor being configured to selectively accumulate the first photocharges; and
a plurality of second pixels spatially separated from the plurality of first pixels, each second pixel of the plurality of second pixels comprising:
a plurality of second photodiodes configured to generate second photocharges based on the incident light;
a second floating diffusion region configured to accumulate the second photocharges, the second floating diffusion region being shared by the plurality of second photodiodes;
a second reset transistor coupled between a reset power supply voltage and the second floating diffusion region; and
a lateral overflow integration capacitor coupled with a capacitor power supply voltage, the lateral overflow integration capacitor being configured to selectively accumulate the second photocharges.

2. The pixel array of claim 1, further comprising:
a semiconductor substrate; and
a deep trench isolation pattern extending vertically in the semiconductor substrate, and at least partially surrounding each first pixel of the plurality of first pixels and each second pixel of the plurality of second pixels in a plan view,
wherein the plurality of first pixels and the plurality of second pixels are disposed in and on the semiconductor substrate, and
wherein the plurality of first pixels and the plurality of second pixels are spatially separated by the deep trench isolation pattern.

3. The pixel array of claim 1, wherein the at least one gain control transistor comprises a first gain control transistor coupled between the first reset transistor and the first floating diffusion region,
wherein the at least one gain control capacitor comprises a first gain control capacitor coupled between a first node and the ground voltage, and
wherein the first node is between the first reset transistor and the first gain control transistor.

4. The pixel array of claim 3, wherein the first gain control transistor is configured to:
turn off based on an illuminance of a driving environment of the image sensor being lower than a reference illuminance, and
turn on based on the illuminance of the driving environment of the image sensor being higher than or equal to the reference illuminance.

5. The pixel array of claim 3, wherein the plurality of first pixels comprises a first pixel and a second pixel adjacent to the first pixel,
wherein the first node of the first pixel is coupled with the first node of the second pixel, and
wherein the first floating diffusion region comprised in one pixel of the first pixel and the second pixel operates as the first gain control capacitor for another pixel of the first pixel and the second pixel.

6. The pixel array of claim 1, wherein the at least one gain control transistor comprises a first gain control transistor and a second gain control transistor,
wherein the first gain control transistor and the second gain control transistor are coupled in series between the first reset transistor and the first floating diffusion region,
wherein the at least one gain control capacitor comprises a first gain control capacitor coupled between a first node and the ground voltage, and a second gain control capacitor coupled between a second node and the ground voltage,
wherein the first node is between the first gain control transistor and the second gain control transistor, and
wherein the second node is between the first reset transistor and the second gain control transistor.

7. The pixel array of claim 6, wherein the first gain control transistor is configured to:
turn off based on an illuminance of a driving environment of the image sensor being lower than a first reference illuminance, and
turn on based on the illuminance of the driving environment of the image sensor being higher than or equal to the first reference illuminance,
wherein the second gain control transistor is configured to:
turn off based on the illuminance of the driving environment of the image sensor being lower than a second reference illuminance, and
turn on based on the illuminance of the driving environment of the image sensor being higher than or equal to the second reference illuminance, and
wherein the second reference illuminance that is higher than the first reference illuminance.

8. The pixel array of claim 6, wherein the plurality of second pixels comprises a first pixel and a second pixel adjacent to the first pixel,
wherein the first node of the first pixel is coupled with the first node of the second pixel, and
wherein at least one of the first gain control capacitor and the first floating diffusion region comprised in one pixel of the first pixel and the second pixel operates as the second gain control capacitor for another pixel of the first pixel and the second pixel.

9. The pixel array of claim 1, wherein the lateral overflow integration capacitor is coupled between the capacitor power supply voltage and the second floating diffusion region, and
wherein the lateral overflow integration capacitor is directly coupled with the second floating diffusion region.

10. The pixel array of claim 1, wherein each second pixel of the plurality of second pixels further comprises:
a third gain control transistor coupled between the second reset transistor and the second floating diffusion region,
wherein the lateral overflow integration capacitor is coupled between a third node and the capacitor power supply voltage, and
wherein the third node is between the second reset transistor and the third gain control transistor.

11. The pixel array of claim 1, wherein each second pixel of the plurality of second pixels further comprises:
a discharge transistor coupled between the second reset transistor and the lateral overflow integration capacitor.

12. The pixel array of claim 1, wherein a second number of pixels of the plurality of second pixels is equal to a first number of the plurality of first pixels.

13. The pixel array of claim 1, wherein a second number of pixels of the plurality of second pixels is smaller than a first number of the plurality of first pixels.

14. An image sensor comprising:
a pixel array comprising a plurality of first pixels and a plurality of second pixels, a first configuration of the plurality of first pixels being different from a second configuration of the plurality of second pixels, and the plurality of first pixels being spatially separated from the plurality of second pixels;
a row driver configured to drive the pixel array by units of rows; and
a readout block configured to generate a plurality of output signals based on a plurality of pixel signals output from the pixel array,
wherein each first pixel of the plurality of first pixels comprises:
a plurality of first photodiodes configured to generate first photocharges based on incident light;
a first floating diffusion region configured to accumulate the first photocharges, the first floating diffusion region being shared by the plurality of first photodiodes;
a first reset transistor and at least one gain control transistor coupled in series between a pixel power supply voltage and the first floating diffusion region; and
at least one gain control capacitor coupled to a ground voltage and coupled between the first reset transistor and the at least one gain control transistor, the at least one gain control capacitor being configured to selectively accumulate the first photocharges, and
wherein each second pixel of the plurality of second pixels comprises:
a plurality of second photodiodes configured to generate second photocharges based on the incident light;
a second floating diffusion region configured to accumulate the second photocharges, the second floating diffusion region being shared by the plurality of second photodiodes;
a second reset transistor coupled between a reset power supply voltage and the second floating diffusion region; and
a lateral overflow integration capacitor coupled to a capacitor power supply voltage, the lateral overflow integration capacitor being configured to selectively accumulate the second photocharges.

15. The image sensor of claim 14, wherein the plurality of first pixels comprise a first-first pixel disposed in a first row,
wherein the plurality of second pixels comprise a second-first pixel disposed in the first row,
wherein a first pixel signal generated from the first-first pixel and a second pixel signal generated from the second-first pixel are simultaneously output, and
wherein the readout block is further configured to simultaneously perform sensing operations on the first pixel signal and the second pixel signal.

16. The image sensor of claim 15, wherein the readout block is further configured to:
sense the first pixel signal based on a first operation timing, and
sense the second pixel signal based on a second operation timing different from the first operation timing.

17. The image sensor of claim 14, further comprising:
an image processor configured to perform an image processing operation based on the plurality of output signals.

18. The image sensor of claim 17, wherein the image processor is further configured to:
perform an image compensating operation using output signals generated by the plurality of second pixels from among the plurality of output signals.

19. The image sensor of claim 18, wherein the image processor is further configured to:
perform the image compensating operation based on a second number of pixels of the plurality of second pixels being smaller than a first number of pixels of the plurality of first pixels.

20. A pixel array of an image sensor comprising:
a semiconductor substrate;
a plurality of first pixels and a plurality of second pixels disposed in and on the semiconductor substrate, a first configuration of the plurality of first pixels being different from a second configuration of the plurality of second pixels; and
a deep trench isolation pattern extending vertically in the semiconductor substrate, and at least partially surrounding each first pixel of the plurality of first pixels and each second pixel of the plurality of second pixels in a plan view, the plurality of first pixels and the plurality of second pixels being spatially separated by the deep trench isolation pattern,
wherein each first pixel of the plurality of first pixels comprises:
a plurality of first photodiodes configured to generate first photocharges based on incident light;
a first floating diffusion region configured to accumulate the first photocharges, the first floating diffusion region being shared by the plurality of first photodiodes;
a plurality of first transfer transistors coupled between the plurality of first photodiodes and the first floating diffusion region, respectively;
a first reset transistor, a first gain control transistor and a second gain control transistor coupled in series between a pixel power supply voltage and the first floating diffusion region;
a first gain control capacitor coupled between a first node and a ground voltage, the first node being between the first gain control transistor and the second gain control transistor;
a second gain control capacitor coupled between a second node and the ground voltage, the second node being between the first reset transistor and the first gain control transistor; and
a first driving transistor and a first selection transistor coupled in series between the pixel power supply voltage and a first output terminal, the first driving transistor having a first gate coupled with the first floating diffusion region, the first selection transistor having a second gate coupled with a first selection signal, and
wherein each second pixel of the plurality of second pixels comprises:
a plurality of second photodiodes configured to generate second photocharges based on the incident light;
a second floating diffusion region configured to accumulate the second photocharges, the second floating diffusion region being shared by the plurality of second photodiodes;
a plurality of second transfer transistors coupled between the plurality of second photodiodes and the second floating diffusion region, respectively;
a second reset transistor coupled between a reset power supply voltage and the second floating diffusion region;
a lateral overflow integration capacitor coupled between a capacitor power supply voltage and the second floating diffusion region, the lateral overflow integration capacitor being configured to selectively accumulate the second photocharges;
a discharge transistor coupled between the second reset transistor and the lateral overflow integration capacitor; and
a second driving transistor and a second selection transistor coupled in series between the pixel power supply voltage and a second output terminal, the second driving transistor having a third gate coupled with the second floating diffusion region, the second selection transistor having a fourth gate coupled with a second selection signal.
